(19) United States
(12) Patent Application Publication
(10) Pub. No.: US 2017/0062675 A1
(43) Pub. Date: Mar. 2, 2017

(54) METHOD OF MANUFACTURING LIGHT EMITTING DIODE

(71) Applicant: SAMSUNG ELECTRONICS CO., LTD., Suwon-si (KR)

(72) Inventors: Jin-young Lim, Gwacheon-si (KR); Tan Sakong, Seoul (KR); Eun-deok Sim, Yongin-si (KR); Suk-ho Yoon, Seoul (KR); Jeong-wook Lee, Yongin-si (KR)

(73) Assignee: SAMSUNG ELECTRONICS CO., LTD., Suwon-si (KR)

(21) Appl. No.: 15/219,454

(22) Filed: Jul. 26, 2016

(30) Foreign Application Priority Data
Aug. 26, 2015 (KR) 10-2015-0120545

(51) Int. Cl. H01L 33/58; H01L 33/00; H01L 33/32; H01L 33/16; H01L 33/44

(52) U.S. Cl. CPC H01L 33/58; H01L 33/16; H01L 33/44; H01L 33/32; H01L 33/0075; H01L 2933/0025; H01L 2933/0058

(57) ABSTRACT

A method of manufacturing a light emitting diode (LED) includes forming a first material layer on a substrate, forming a second material layer on the first material layer, forming a photomask pattern on the second material layer, performing a first etching on the second material layer and a portion of the first material layer by using the photomask pattern as an etch mask, removing the photomask pattern, and forming a plurality of isolated structures by performing a second etching on the remaining portion of the first material layer until a top surface of the substrate is exposed.

### CROSS-REFERENCE TO RELATED APPLICATION

This application claims priority from Korean Patent Application No. 10-2015-0120545, filed on Aug. 26, 2015, in the Korean Intellectual Property Office, the disclosure of which is incorporated herein in its entirety by reference.

### BACKGROUND

Methods consistent with exemplary embodiments relate to a method of manufacturing a light emitting diode (LED), and more particularly, to a method of manufacturing an LED, which may include forming patterns on a substrate by using materials having different refractive indices to improve light extraction efficiency.

An LED is a light source that has a longer lifespan, lower power consumption, and a faster response speed and is more eco-friendly compared to other light sources. Thus, the LED is used as a light source for various products, such as a lighting apparatus and a backlight unit (BLU) of a display apparatus. It is desirable to improve light extraction efficiency of an LED to obtain a high-luminance LED.

### SUMMARY

One or more exemplary embodiments provide a method of manufacturing a light emitting diode (LED) in which a pattern is formed on a substrate by using materials having different refractive indices to improve light extraction efficiency.

Aspects of the inventive concept should not be limited by the above description, and other unmentioned aspects will be clearly understood by one of ordinary skill in the art from example embodiments described herein.

According to an aspect of an exemplary embodiment, there is provided a method of manufacturing an LED. The method includes forming a first material layer on a substrate, forming a second material layer on the first material layer, forming a photomask pattern on the second material layer, performing a first etching on the second material layer and a portion of the first material layer by using the photomask pattern as an etch mask, removing the photomask pattern, and forming a plurality of isolated structures by performing a second etching on the remaining portion of the first material layer until a top surface of the substrate is exposed.

The second material layer may have a thickness greater than a thickness of the first material layer.

The first etching of the second material layer and the portion of the first material layer may include etching the second material layer to form a second material layer pattern having a hemispherical shape or a conic shape.

The first material layer may have a refractive index higher than a refractive index of the substrate, and the second material layer may have a refractive index lower than the refractive index of the substrate.

The first material layer may include a silicon nitride, and the second material layer may include a silicon oxide.

The first etching of the second material layer and the portion of the first material layer may be a dry etching, and the second etching of the remaining portion of the first material layer may be a wet etching.

An etchant for the second etching may include phosphoric acid (H₃PO₄).

The performing the second etching may include adjusting an etch selectivity of the first material layer with respect to the second material layer to be at least 5:1.

The second etching may not substantially etch the substrate.

After the plurality of isolated structures are formed, the method may further include forming a base layer that covers the substrate and the plurality of isolated structures.

According to an aspect of another exemplary embodiment, there is provided a method of manufacturing an LED. The method includes preparing a substrate having a light transmittance characteristic, forming a silicon nitride layer on the substrate, forming a silicon oxide layer on the silicon nitride layer, forming a photomask pattern on the silicon oxide layer, dry etching the silicon oxide layer and a portion of the silicon nitride layer by using the photomask pattern as an etch mask, removing the photomask pattern, forming a plurality of isolated structures by wet etching the remaining portion of the silicon nitride layer until a top surface of the substrate is exposed, forming a base layer that covers the substrate and the plurality of isolated structures, and forming an emission structure on the base layer.

The substrate may include a sapphire substrate.

The emission structure may include a first-conductivity-type semiconductor layer, an active layer, and a second-conductivity-type semiconductor layer.

The wet etching may not substantially etch the substrate.

An etchant for the wet etching of the remaining portion of the silicon nitride layer may include a phosphoric acid (H₃PO₄), and a process temperature of the etchant may range from about 180° C. to about 200° C.

The plurality of isolated structures may respectively have a hemispherical shape or a conic shape.

According to an aspect of still another exemplary embodiment, there is provided a method of manufacturing a light emitting diode (LED). The method includes forming a plurality of patterns on a substrate, upper portions of the plurality of patterns including a first material and lower portions of the plurality of patterns including a second material, the second material having a refractive index that is different from a refractive index of the first material; and forming an emission structure above the plurality of patterns, the emission structure including a first-conductivity-type semiconductor layer, an active layer, and a second-conductivity-type semiconductor layer.

The method may further include forming a base layer positioned between the substrate and the emission structure, wherein the base layer covers the plurality of patterns.

The forming the plurality of patterns may include performing dry etching to form the upper portions and parts of the lower portions of the plurality of patterns, and performing wet etching to form remaining parts of the lower portions of the plurality of patterns.

The first material may include a silicon nitride, and the second material may include a silicon oxide.

### BRIEF DESCRIPTION OF THE DRAWINGS

The above and/or other aspects will be more apparent by describing certain example embodiments with reference to the accompanying drawings, in which:

FIG. 1 is a flow chart illustrating a method of manufacturing a light emitting diode (LED), according to an exemplary embodiment;

FIGS. 2 to 9 are views illustrating a method of manufacturing an LED, according to an exemplary embodiment;

FIG. 10 is a cross-sectional view of an LED manufactured by a method of manufacturing an LED, according to an exemplary embodiment;

FIG. 11 is a cross-sectional view of an LED package including an LED manufactured by a method of manufacturing an LED, according to an exemplary embodiment;

FIGS. 12 and 13 are cross-sectional views of white light source modules including an LED manufactured by a method of manufacturing an LED, according to an exemplary embodiment;

FIG. 14 is a schematic cross-sectional view of a white light source module including an LED manufactured by a method of manufacturing an LED, according to an exemplary embodiment, wherein the white light source module may be applied to a lighting apparatus;

FIG. 15 is an international commission on illumination (CIE) chromaticity diagram of a complete radiator spectrum that may be used for an LED manufactured by a method of manufacturing an LED, according to an exemplary embodiment;

FIG. 16 is a schematic diagram showing a sectional structure of a quantum dot (QD) that may be used as a wavelength conversion material for an LED manufactured by a method of manufacturing an LED, according to an exemplary embodiment;

FIG. 17 is a schematic perspective view of a backlight unit (BLU) including an LED manufactured by a method of manufacturing an LED, according to an exemplary embodiment;

FIG. 18 is a diagram of a direct-light-type BLU including an LED manufactured by a method of manufacturing an LED, according to an exemplary embodiment;

FIG. 19 is a diagram of a BLU including an LED manufactured by a method of manufacturing an LED, according to an exemplary embodiment;

FIG. 20 is a diagram of a direct-light-type BLU including an LED manufactured by a method of manufacturing an LED, according to an exemplary embodiment;

FIG. 21 is an enlarged view of a light source module of FIG. 20;

FIG. 22 is a diagram of a direct-light-type BLU including an LED manufactured by a method of manufacturing an LED according to another exemplary embodiment;

FIGS. 23 to 25 are diagrams of BLUs including LEDs manufactured by a method of manufacturing an LED, according to an exemplary embodiment;

FIG. 26 is a schematic exploded perspective view of a display apparatus including an LED manufactured by a method of manufacturing an LED, according to an exemplary embodiment;

FIG. 27 is a schematic perspective view of a flat-panel lighting apparatus including an LED manufactured by a method of manufacturing an LED, according to an exemplary embodiment;

FIG. 28 is a schematic exploded perspective view of a lighting apparatus including an LED manufactured by a method of manufacturing an LED, according to an exemplary embodiment;

FIG. 29 is a schematic exploded perspective view of a bar-type lighting apparatus including an LED manufactured by a method of manufacturing an LED, according to an exemplary embodiment;

FIG. 30 is a schematic exploded perspective view of a lighting apparatus including an LED manufactured by a method of manufacturing an LED, according to an exemplary embodiment;

FIG. 31 is a schematic diagram of an indoor illumination control network system including an LED manufactured by a method of manufacturing an LED, according to an exemplary embodiment;

FIG. 32 is a schematic diagram of a network system including an LED manufactured by a method of manufacturing an LED, according to an exemplary embodiment;

FIG. 33 is a block diagram of an operation of communicating between a smart engine of an illumination mechanism including an LED manufactured by a method of manufacturing an LED, according to an exemplary embodiment, and a mobile device; and

FIG. 34 is a schematic conceptual diagram of a smart illumination system including an LED manufactured by a method of manufacturing an LED, according to an exemplary embodiment.

### DETAILED DESCRIPTION

Hereinafter, certain exemplary embodiments will be described as follows with reference to the attached drawings.

As used herein, the term “and/or” includes any and all combinations of one or more of the associated listed items. Expressions such as “at least one of,” when preceding a list of elements, modify the entire list of elements and do not modify the individual elements of the list.

The inventive concept will now be described more fully hereinafter with reference to the accompanying drawings, in which exemplary embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Meanwhile, spatially relative terms, such as “between” and “directly between” or “adjacent to” and “directly adjacent to” and the like, which are used herein for ease of description to describe one element or feature's relationship to another element(s) or feature(s) as illustrated in the figures, should be interpreted similarly.

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concept.

As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. The inventive concept will now be described more fully with reference to the accompanying drawings, in which embodiments of the inventive concept are shown.

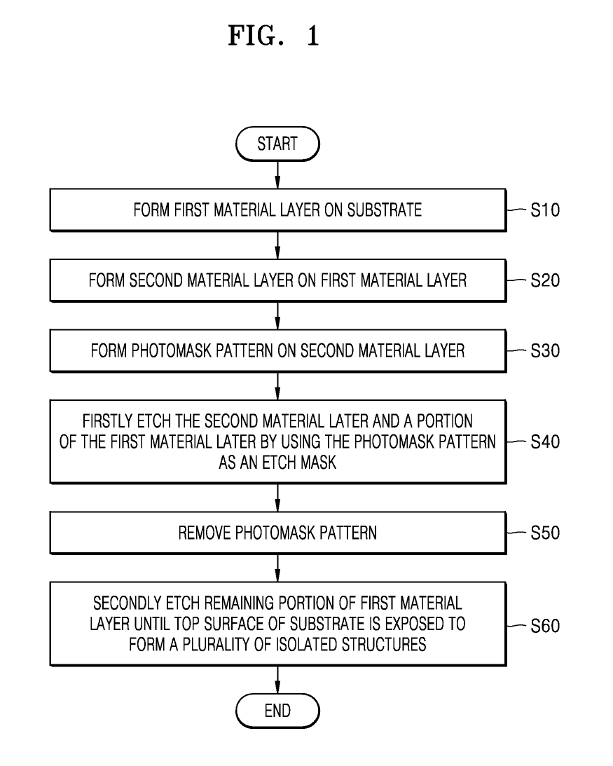

FIG. 1 is a flowchart illustrating a method of manufacturing a light emitting diode (LED) according to an exemplary embodiment.

Referring to FIG. 1, the method of manufacturing the LED according to an exemplary embodiment may include forming a first material layer on a substrate (S10), forming a second material layer on the first material layer (S20), forming a photomask pattern on the second material layer (S30), firstly etching the second material layer and a portion of the first material layer by using the photomask pattern as an etch mask (S40), removing the photomask pattern (S50), forming a plurality of isolated structures by secondly etching the remaining portion of the first material layer until a top surface of the substrate is exposed (S60).

In the method, a first material layer may be formed on the substrate (S10). The substrate may include a light transmission characteristic. When the substrate includes a light transmission material or is formed to have a predetermined thickness or less, the substrate may have the light transmission characteristic.

The first material layer formed on the substrate may have a dielectric material having a light transmission characteristic. For example, the first material layer may include silicon nitride (SiₓN_{y}).

In addition, the second material layer may be formed on the first material layer (S20). The second material layer formed on the first material layer may include a dielectric material having a light transmission characteristic. The second material layer may include a material having an etch rate and a refractive index different from those of a material included in the first material layer. The second material layer may include a material having adhesion (or improved adhesion) to the first material layer. For example, the second material layer may include silicon oxide (SiₓO_{y}). The second material layer may have a greater thickness than the first material layer.

A photomask pattern may be formed on the second material layer (S30), and the second material layer and a portion of the first material layer may be firstly etched by using the photomask pattern as an etch mask (S40). The photomask pattern may include photoresist. The photomask pattern may be a regularly arranged pattern or an irregularly arranged pattern.

The first etching process may be a dry etching process. The second material layer and the portion of the first material layer, which are exposed by the photomask pattern, may be dry etched by using the photomask pattern as an etch mask. That is, the second material layer may constitute upper portions of the plurality of isolated structures through the dry etching process. The dry etching process may be performed to remove only the portion of the first material layer. That is, the dry etching process may be performed not to expose a top surface of the substrate.

In the related art, when the first material layer is dry etched, damage may be applied to the surface of the substrate. When the surface of the substrate sustains damage, the damage may affect the formation of a semiconductor layer to be grown on the surface of the substrate in a subsequent process. Also, when failures occur in a subsequent process and a reworking process is performed, the manufacturing cost may increase because the substrate cannot be reused. This problem may be avoided according to the exemplary embodiment because the dry etching process may be performed not to expose a top surface of the substrate.

A residue of the photomask pattern, which may remain after the dry etching process, may be removed (S50), and the remaining portion of the first material layer may be secondly etched until a top surface of the substrate is exposed, thereby forming a plurality of isolated structures (S60).

The second etching process may be a wet etching process. The wet etching process may be performed by controlling an etchant and etching conditions such that an etch rate of the second material layer is lower than an etch rate of the first material layer. That is, the etching of the second material layer may be hardly performed during the etching of the first material layer.

By using the above-described process, a plurality of isolated structures including upper portions and lower portions including different materials may be formed on the substrate. Each of the plurality of isolated structures may have a size that is in the range of about 5 nm to about 500 μm. The plurality of isolated structures may have any pattern capable of regularly or irregularly improving light extraction efficiency. In an exemplary embodiment, each of the plurality of isolated structures may have a hemispherical structure or a conic structure.

Hereinafter, a method of manufacturing the plurality of isolated structures and a method of manufacturing an LED including the plurality of isolated structures will be described.

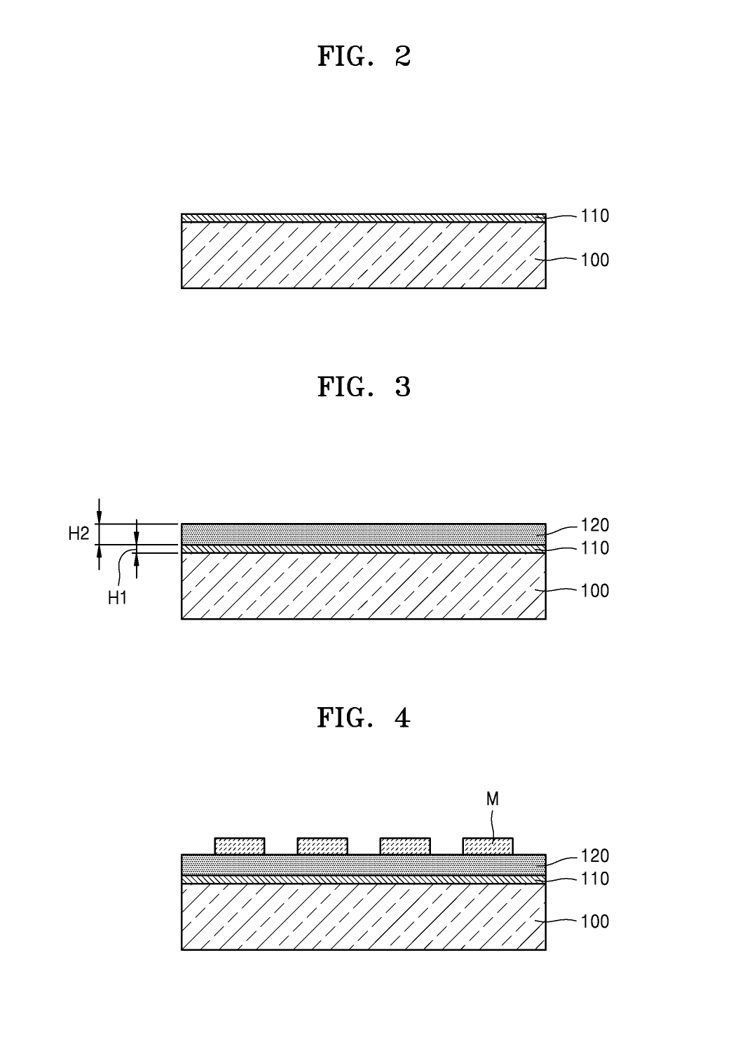

FIGS. 2 to 9 are views illustrating a method of manufacturing an LED according to an exemplary embodiment.

Referring to FIG. 2, a first material layer 110 may be formed on a substrate 100.

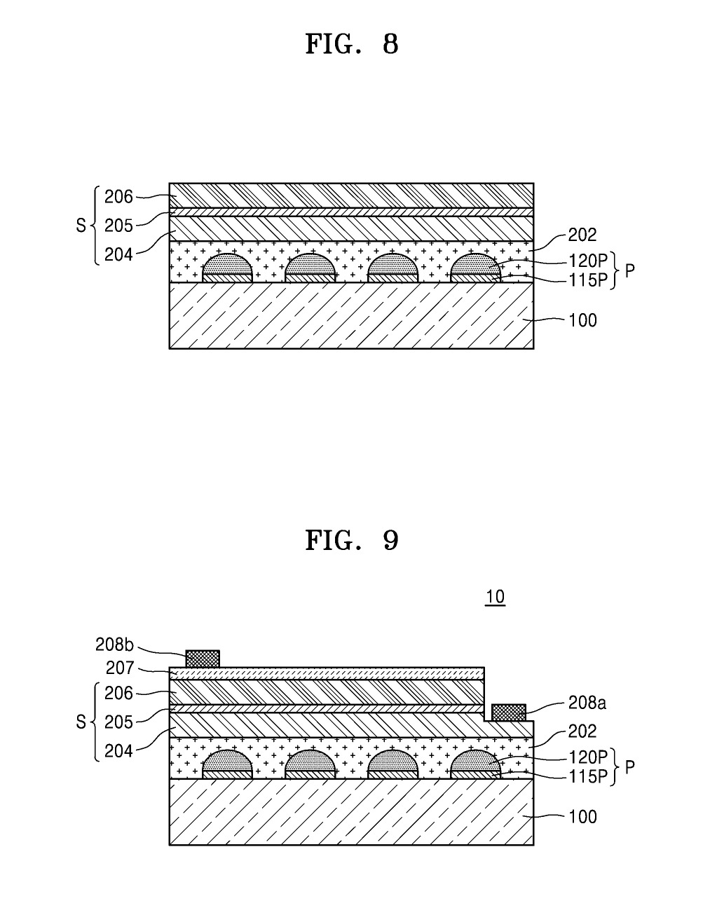

The substrate 100 may be located under an emission structure (refer to S in FIG. 8) and support the emission structure. The substrate 100 may receive heat generated by a first-conductivity-type semiconductor layer (refer to 204 in FIG. 8) through a base layer (refer to 202 in FIG. 8) and externally emit the received heat. Also, the substrate 100 may have a light transmission characteristic. When the substrate 100 includes a light transmission material or is formed to have a predetermined thickness or less, the substrate 100 may have a light transmission characteristic.

An insulating substrate, a conductive substrate, or a semiconductor substrate may be used as the substrate 100. For example, the substrate 100 may include sapphire (Al₂O₃), gallium nitride (GaN), silicon (Si), germanium (Ge), gallium arsenide (GaAs), zinc oxide (ZnO), silicon germanium (SiGe), silicon carbide (SiC), gallium oxide (Ga₂O₃), lithium gallium oxide (LiGaO₂), lithium aluminum oxide (LiAlO₂), or magnesium aluminum oxide (MgAl₂O₄).

In exemplary embodiments, the substrate 100 may mainly include sapphire, silicon carbide, or silicon substrate. A sapphire substrate or a silicon substrate is lower cost compared to a silicon carbide substrate.

In some cases, before or after the emission structure is formed, the substrate 100 may be completely or partially removed during the manufacture of the LED to improve optical characteristics or electrical characteristics of the LED.

For example, when the substrate 100 is a sapphire substrate, the removal of the substrate 100 may be performed by irradiating laser beams through the substrate 100 to an interface between the substrate 100 and the base layer. When the substrate 100 is a silicon substrate or a silicon carbide substrate, the substrate 100 may be removed by a polishing process or an etching process.

In addition, another substrate (e.g., a support substrate) may be used to remove the substrate 100. To improve optical efficiency of an LED, the support substrate may be adhered to a reverse surface of the substrate 100 by using a reflective metal or a reflective structure may be inserted into an adhesive layer.

When the substrate 100 is a sapphire substrate, the sapphire substrate may have a crystal structure with hexa-rhombo symmetry having c-axial and a-axial lattice constants of 13.001 Å and 4.758 Å, respectively, and a C(0001) plane, an A(1120) plane, and an R(1102) plane. In this case, since the C(0001) plane is relatively easy to grow a nitride thin film and stable at a high temperature, the sapphire substrate may be mainly used as a nitride growth substrate.

In another example, the substrate 100 may be a silicon substrate. Since the silicon substrate is suitable for a large diameter of substrates and relatively inexpensive, mass productivity may increase. A difference in a lattice constant between a silicon substrate as a substrate surface and a gallium nitride may be about 17%. Thus, a technique of inhibiting occurrence of crystal defects due to the difference in a lattice constant may be needed. The silicon substrate may absorb light emitted by a GaN-based semiconductor to reduce optical efficiency of an LED. Thus, the silicon substrate may be removed and a support substrate, such as a germanium substrate, a ceramic substrate, or a metal substrate, may be further formed and used.

The first material layer 110 may be formed on the substrate 100. The first material layer 110 may include a dielectric material. The first material layer 110 may include a light transmission material. The present embodiment describes an example in which the first material layer 110 includes a silicon nitride SiₓN_{y}. The first material layer 110 may be formed to have a thickness of about 150 nm to about 250 nm.

Referring to FIG. 3, a second material layer 120 may be formed on the first material layer 110.

The second material layer 120 may be formed on the first material layer 110 and include a dielectric material. The second material layer 120 may include a light transmission material. The second material layer 120 may include a material having an etch rate and a refractive index different from those of a material included in the first material layer 110. The present embodiment describes an example in which the second material layer 120 includes silicon oxide (SiₓO_{y}). A thickness H2 of the second material layer 120 may be greater than a thickness H1 of the first material layer 110. The second material layer 120 may be formed to have a thickness H2 of about 1.2 μm to about 1.5 μm.

The formation of the second material layer 120 using silicon oxide (SiₓO_{y}) may include supplying a silicon source material, such as silane (SiH₄) or TEOS, into a reaction furnace and applying heat. Thus, the silicon material layer 120 may be naturally formed by combining the silicon source material with oxygen remaining in the reaction furnace. Since the above-described process is a known process, detailed descriptions thereof are omitted.

Although grown silicon oxide (SiₓO_{y}) is SiO₂ having a thickness of about 1 μm to about 1.5 μm, the grown thickness may vary, and the combined amount of oxygen may be stoichiometrically slightly less or more than 2 depending on forming conditions.

Referring to FIG. 4, a photomask pattern M may be formed on the second material layer 120.

After the second material layer 120 is coated with photoresist, although not shown, the photoresist may be exposed and developed by using a mask and a light source. Thus, as shown in FIG. 4, only a portion of the photoresist may remain, and the remaining portion of the photoresist may be removed, thereby completing formation of the photomask pattern M.

The photomask pattern M may be a regularly arranged pattern or an irregularly arranged pattern. Also, a thickness of the photomask pattern M may be controlled to affect a plurality of isolated structures (refer to P in FIG. 6) in a subsequent process.

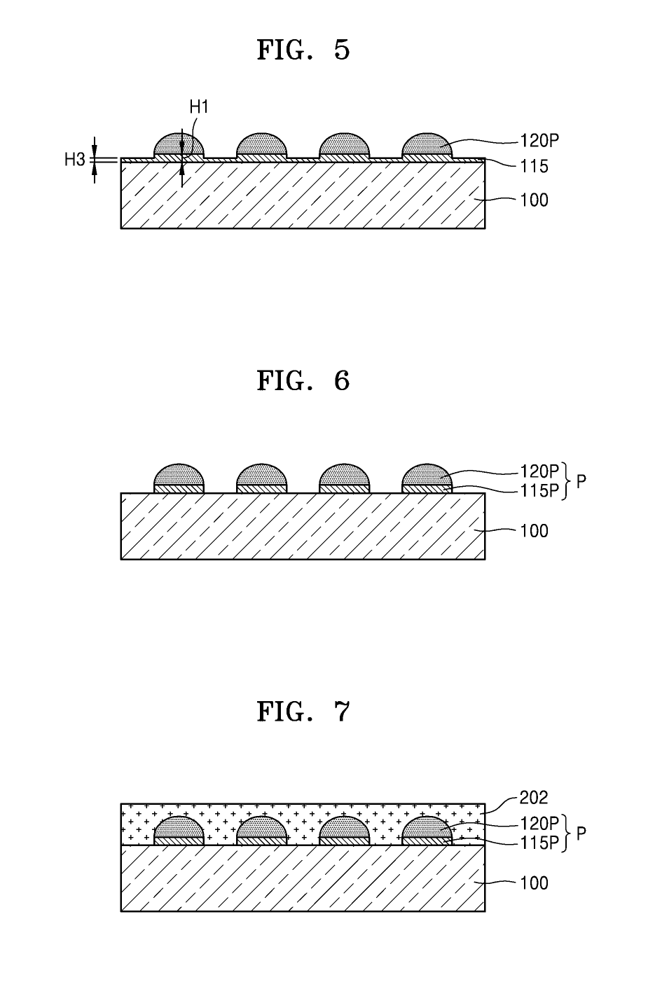

Referring to FIG. 5, the second material layer (refer to 120 in FIG. 4) and a portion of the first material layer (refer to 110 in FIG. 4) may be firstly etched by using the photomask pattern (refer to M in FIG. 4) as an etch mask, and the photomask pattern may be removed.

The first etching process may be a dry etching process. A portion of the second material layer, which is exposed by the photomask pattern, may be etched by using the photomask pattern as an etch mask to form a second material layer pattern 120P. Also, the portion of the first material layer may be etched to form a first material layer bent portion 115. Through the first etching process, the second material layer pattern 120P may constitute upper portions of a plurality of isolated structures (refer to P of FIG. 6). That is, due to the first etching process, a thickness H1 of a portion of the first material layer bent portion 115, which is covered with the second material layer pattern 120P and unetched, may be different from a thickness H3 of a portion of the first material layer bent portion 115, which is exposed and etched.

The dry etching process may be performed to remove only the portion of the first material layer. Specifically, the dry etching process may be performed until a thickness H3 of an exposed and etched portion of the first material layer bent portion 115 is about 50 nm so that a top surface of the substrate 100 may not be exposed.

In the related art, when the first material layer is dry etched, damage may be applied to the surface of the substrate 100. When the surface of the substrate 100 sustains damage, the damage may affect the formation of a semiconductor layer to be grown on the surface of the substrate 100 during a subsequent process. Also, when failures occur in a subsequent process and a reworking process is performed, the manufacturing cost may increase because the substrate 100 cannot be reused.

This problem may be avoided according to the exemplary embodiment because the dry etching process may be performed not to expose a top surface of the substrate. Accordingly, the method of manufacturing the LED according to the present embodiment may reduce the manufacturing cost of the LED.

The dry etching process may be performed by using, for example, a reactive ion etching (RIE) process or an inductively coupled plasma (ICP) etching process.

The second material layer may be patterned by using a dry etching process to form the second material layer pattern 120P. Although FIG. 5 illustrates an example in which the second material layer pattern 120P has a hemispherical shape, a shape of the second material layer pattern 120P is not limited thereto and may be variously modified. For example, the second material layer pattern 120P may have a conic shape, a cylindrical shape, a triangular shape, a quadrangular shape, a square shape, a tetragonal shape, a trapezoidal shape, or a strip shape.

A residue of the photomask pattern, which remains after the dry etching process, may be removed by using an ashing process and a stripping process.

Referring to FIG. 6, the remaining portion of the first material layer bent portion (refer to 115 in FIG. 5) may be secondly etched until a portion of the top surface of the substrate 100 is exposed, thereby forming a plurality of isolated structures P.

The second etching process may be a wet etching process. The wet etching process may be performed by controlling an etchant and etching conditions such that an etch rate of the second material layer pattern 120P is lower than an etch rate of the first material layer bent portion. That is, the etching of the second material layer pattern 120P may be hardly performed during the etching of the first material layer bent portion. An etch selectivity of a material forming the first material layer compared to a material forming the second material layer with respect to an etchant used for the wet etching process may be equal to or greater than 5:1. Also, the substrate 100 may have a low etch rate with respect to the etchant used for the wet etching process.

For example, the etchant used for the wet etching process may contain phosphoric acid (H₃PO₄). An etch selectivity of silicon nitride (Si₃N₄) compared to silicon oxide (SiO₂) with respect to the phosphoric acid at a temperature of about 180° C. may be approximately 105:10. Also, an etch selectivity of silicon nitride compared to silicon oxide with respect to the phosphoric acid at a temperature of about 200° C. may be approximately 178:32. Accordingly, the wet etching process may be performed by heating a solution containing phosphoric acid to a temperature of about 180° C. to about 200° C. In exemplary embodiments, the etchant is not limited to the phosphoric acid, and the process conditions may vary depending on several process parameters.

To form the first material layer pattern 115P by etching a portion of the first material layer bent portion by using the second material layer pattern 120P as a hard mask, the etching of the second material layer pattern 12P may be hardly performed during the etching of the first material layer bent portion. However, process conditions may be controlled such that the second material layer pattern 120P is partially etched and has a hemispherical shape or a conic shape.

During the etching of the second material layer (refer to 120 in FIG. 4), various process conditions may be adjusted. For example, a thickness or shape of the photomask pattern (refer to M in FIG. 4) may be adjusted or a dry etch time or the concentration of a solution used for the wet etching process may be varied so that the second material layer disposed under the photomask pattern may be overetched and have substantially the same shape as the second material layer pattern 120P. As a result, a plurality of hemispherical or conic isolated structures P may be formed as shown in FIG. 6.

In general, when patterns are formed by using materials having different refractive indices on a substrate, light extraction efficiency of an LED may increase. However, after the patterns are formed, it may be very difficult to clean the surface of the substrate. As a result, a semiconductor layer, for example, a gallium nitride (GaN) layer, which is to be grown on the surface of the substrate in a subsequent process, may not be properly grown. Accordingly, a process of etching a portion of the surface of the substrate may be performed to substantially prevent a residue of materials forming the patterns from remaining on the surface of the substrate. However, when the etching process is performed, source gases for forming the gallium nitride layer may be non-uniformly adsorbed on the surface of the substrate so that the gallium nitride may not be properly grown.

On the other hand, in a method of manufacturing an LED according to an exemplary embodiment, a plurality of material layers may be formed by using materials having different etch rates, and a plurality of etching processes may be performed by using different methods. Thus, a plurality of isolated structures P may be formed on the substrate without applying damage to the substrate. Accordingly, the semiconductor layer may be properly formed on the surface of the substrate in a subsequent process, and light transmission efficiency may increase.

When the plurality of isolated structures P are provided on the substrate 100, light that may not contribute toward luminance due to total internal reflection may be reflected or refracted by the plurality of isolated structures P to increase light transmission efficiency of the LED. In other words, by applying refraction factors to paths of light traveling within the LED only at a total reflection angle, the probability that light will be reflected and refracted by the refraction factors may be increased to improve light extraction efficiency.

In addition, when each of the plurality of isolated structures P includes a double layer, since more reflection and refraction factors are formed in the LED due to a difference in a refractive index between different materials, light may be refracted and extracted more effectively. The first material layer pattern 115P included in lower portions of the plurality of isolated structures P may have a different refractive index from the second material layer pattern 120P included in upper portions of the plurality of isolated structures P. Also, the first and second material layer patterns 115P and 120P may have different refractive indices from the substrate 100.

In exemplary embodiments, when the substrate 100 includes sapphire, the first material layer (refer to 110 in FIG. 3) includes Si₃N₄, and the second material layer includes SiO₂, sapphire may have a refractive index of 1.76, Si₃N₄ may have a refractive index of 2.01, and SiO₂ may have a refractive index of 1.45. By using materials having different refractive indices, the first material layer may be configured to have a higher refractive index than that of the substrate 100, and the second material layer may be configured to have a lower refractive index than that of the substrate 100 so that light extraction efficiency may be improved.

Referring to FIG. 7, a base layer 202 may cover the substrate 100 and the plurality of isolated structures P.

The base layer 202 may be a semiconductor layer on which an emission structure (refer to S in FIG. 8) is to be grown. For example, the base layer 202 may include InₓAl_{y}Ga_{(1-x-y)} (0≦x≦1, 0≦y≦1), for example, GaN, AlN, AlGaN, InGaN, or InGaNAlN. Depending on embodiments, the base layer 202 may include ZrB₂, HfB₂, ZrN, HfN, or TiN. Also, the base layer 202 may be formed by combining a plurality of layers or gradually varying a composition of a material. In some exemplary embodiments, the base layer 202 may be omitted.

Referring to FIG. 8, an emission structure S may be formed on the base layer 202.

The emission structure S may include a first-conductivity-type semiconductor layer 204, an active layer 205, and a second-conductivity-type semiconductor layer 206. Each of the first-conductivity-type semiconductor layer 204 and the second-conductivity-type semiconductor layer 206 may have a single layer structure. However, in another example, each of the first-conductivity-type semiconductor layer 204 and the second-conductivity-type semiconductor layer 206 may have a multilayered structure having different compositions or thicknesses. For example, the first-conductivity-type semiconductor layer 204 and the second-conductivity-type semiconductor layer 206 may include carrier injection layers capable of improving electron injection efficiency and hole injection efficiency, respectively. In another example, each of the first-conductivity-type semiconductor layer 204 and the second-conductivity-type semiconductor layer 206 may include a superlattice structure having one of various structures.

A current diffusion layer (not shown) may be further formed in a portion of the first-conductivity-type semiconductor layer 204 adjacent to the active layer 205. The current diffusion layer may have a structure formed by repetitively stacking a plurality of InₓAl_{y}Ga_{(1-x-y)}N layers having different compositions or different dopant contents or partially include an insulating material layer.

The second-conductivity-type semiconductor layer 1506 may further include an electron blocking layer (not shown) disposed in a portion adjacent to the active layer 205. The electron blocking layer may include a structure in which a plurality of layers including InₓAl_{y}Ga_{(1-x-y)}N having different compositions are stacked, or at least one layer including Al_{y}Ga_{(1-y)}N. The electron blocking layer may have a higher bandgap than the active layer 205 and substantially prevent electrons from being transported to the second-conductivity-type semiconductor layer 206.

The manufacture of the emission structure S may include supplying an organic metal compound gas (e.g., trimethyl gallium (TMG) or trimethyl aluminium (TMA)) and a nitrogen-containing gas (e.g., ammonia gas) as reactive gases into a reaction container into which a substrate 100 is loaded, maintaining the substrate 100 at a high temperature of about 900° C. to about 1100° C., and stacking a GaN-based compound semiconductor as an undoped type, an n type, or a p type by supplying a dopant gas while growing the GaN-based compound semiconductor on the substrate 100. Silicon may be known as an n-type dopant, and a p-type dopant may be zinc (Zn), cadmium (Cd), beryllium (Be), magnesium (Mg), cadmium (Ca), or barium (Ba). Among these, Mg or Zn may be typically used as the p-type dopant.

Also, the active layer 205 interposed between the first-conductivity-type semiconductor layer 204 and the second-conductivity-type semiconductor layer 206 may have a multiple quantum well (MQW) structure in which a quantum well layer and a quantum barrier layer are alternately stacked. For example, when the active layer 205 includes a nitride semiconductor, a GaN/InGaN structure may be used. However, the active layer 205 may have a single quantum well (SQW) structure.

Referring to FIG. 9, an LED 10 may include a transparent electrode layer 207, a first electrode 208a, and a second electrode 208b, which are formed on the emission structure S.

The transparent electrode layer 207 formed on the second-conductivity-type semiconductor layer 206 may include a material selected from the group consisting of silver (Ag), nickel (Ni), aluminium (Al), rhodium (Rh), palladium (Pd), iridium (Jr), ruthenium (Ru), magnesium (Mg), zinc (Zn), platinum (Pt), and gold (Au) based on a light reflection function and an ohmic contact with the second-conductivity-type semiconductor layer 206. The transparent electrode layer 207 may be formed by using a sputtering process or a deposition process.

The first electrode 208a or the second electrode 208b may include a material, such as Ag, Ni, Al, Rh, Pd, Jr, Ru, Mg, Zn, Pt, or Au, or have a structure including at least two layers including Ni/Ag, Zn/Ag, Ni/Al, Zn/Al, Pd/Ag, Pd/Al, Ir/Ag. Ir/Au, Pt/Ag, Pt/Al, Ni/Ag/Pt.

The LED 10 may have a structure in which the first electrode 208a and the second electrode 208b face the same surface as a light extraction surface.

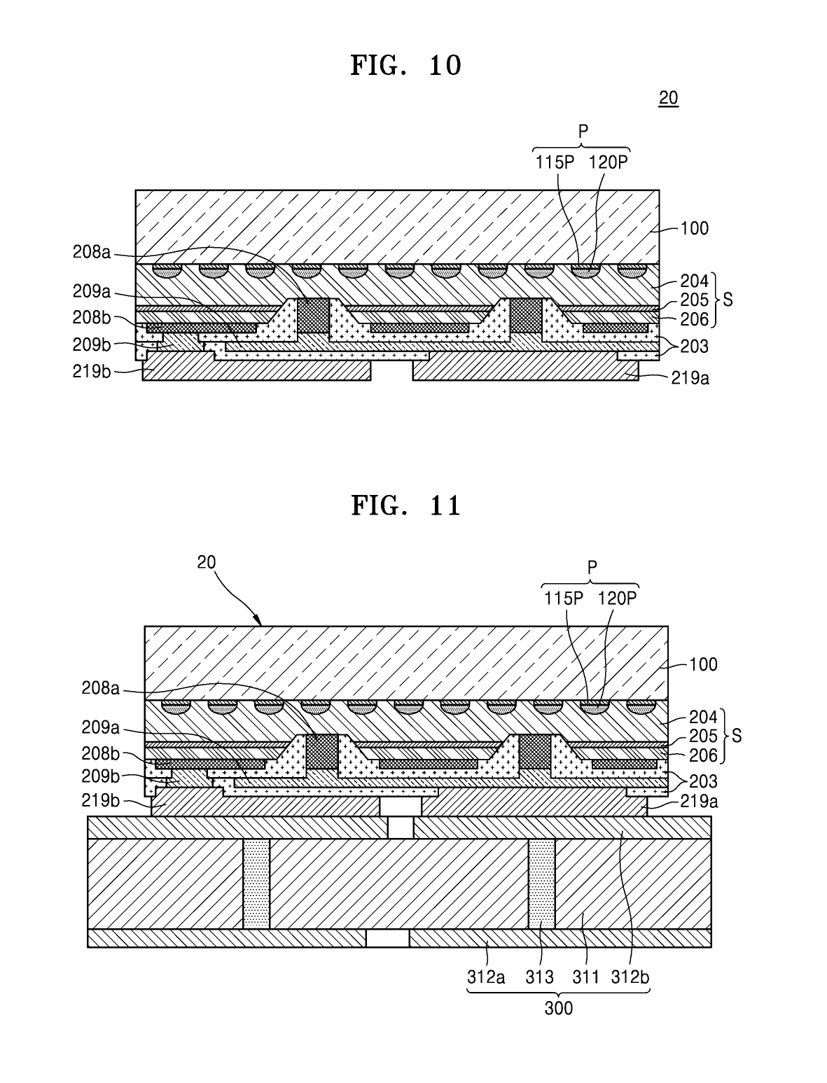

FIG. 10 is a cross-sectional view of an LED 20 manufactured by a method of manufacturing an LED according to an exemplary embodiment.

Referring to FIG. 10, the LED 20 may include a plurality of isolated structures P and an emission structure S located on one surface of a substrate 100, and a first electrode 208a and a second electrode 208b located on a side of the emission structure S, which faces opposite to the substrate 100. Also, the LED 20 may include an insulation unit 203 covering the first electrode 208a and the second electrode 208b. The first electrode 208a and the second electrode 208b may be connected to a first external connection terminal 219a and a second external connection terminal 219b through a first electrical connection unit 209a and a second electrical connection unit 209b, respectively. A first electrode structure may include the first electrode 208a and the first electrical connection unit 209a, and a second electrode structure may include the second electrode 208b and the second electrical connection unit 209b.

The emission structure S may include a first-conductivity-type semiconductor layer 204, an active layer 205, and a second-conductivity-type semiconductor layer 206, which are sequentially located on the substrate 100. The first electrode 208a may be a conductive via, which may penetrate the second-conductivity-type semiconductor layer 206 and the active layer 205 and be connected to the first-conductivity-type semiconductor layer 204. The second electrode 208b may be connected to the second-conductivity-type semiconductor layer 206.

The first electrode 208a and the second electrode 208b may be formed by depositing a conductive ohmic material on the emission structure S.

As described above, each of the first electrode 208a and the second electrode 208b may include one or more of various materials or stack structures to improve ohmic characteristics or reflection characteristics.

The insulation unit 203 may include an open region to expose at least portions of the first electrode 208a and the second electrode 208b. The first external connection terminal 219a and the second external connection terminal 219b may be connected to the first electrode 208a and the second electrode 208b, respectively. The insulation unit 203 may include silicon oxide and/or silicon nitride and be formed to have a thickness of about 0.01 μm to about 3 μm.

The first external connection terminal 219a and the second external connection terminal 219b may be arranged in the same direction and mounted as a flip-chip type on a module, such as a lead frame. In this case, the first external connection terminal 219a and the second external connection terminal 219b may face the same direction.

The LED 20 according to the present embodiment may include a plurality of isolated structures P formed on one surface of the substrate 100. The plurality of isolated structures P formed on one surface of the substrate 100 may be formed by using the method of manufacturing the LED described with reference to FIGS. 2 to 6.

In an exemplary embodiment, when the plurality of isolated structures P are formed on the substrate 100, light emitted by the active layer 205 may travel along various paths. Thus, as described above, a percentage of light absorbed by a semiconductor layer of the total light may be reduced and a light scattering rate may increase so that light extraction efficiency may increase.

The first external connection terminal 219a and the second external connection terminal 219b may be respectively connected to the first electrical connection unit 209a and the second electrical connection unit 209b and function as external terminals of the LED 20. For example, the first external connection terminal 219a and the second external connection terminal 219b may include gold (Au), silver (Ag), aluminum (Al), titanium (Ti), tungsten (W), copper (Cu), tin (Sn), nickel (Ni), platinum (Pt), chromium (Cr), nickel tin (NiSn), titanium tungsten (TiW), gold tin (AuSn) or an eutectic metal thereof. In this case, when each of the first external connection terminal 219a and the second external connection terminal 219b is mounted on the module (refer to 300 in FIG. 11) and adhered to the module by using an eutectic metal, additional solder bumps, which are typically used in a flip-chip bonding process, may not be used. A mounting technique using an eutectic metal may produce improved heat radiation effects than a mounting technique using solder bumps. In this case, to obtain excellent heat radiation effects, each of the first external connection terminal 219a and the second external connection terminal 219b may be formed to have a larger area.

FIG. 11 is a cross-sectional view of an LED package including an LED 20 manufactured by a method of manufacturing an LED according to an exemplary embodiment.

Referring to FIG. 11, the LED 20 may be mounted on a module 300. Since the LED 20 is similar to or the same as described with reference to FIG. 10, detailed descriptions thereof are omitted. The module 300 may include an upper electrode layer 312b and a lower electrode layer 312a respectively formed on a top surface and a bottom surface of a main body 311, and a via 313 formed through the main body 311 to connect the upper electrode layer 312b and the lower electrode layer 312a. The main body 311 may include a resin, ceramic, or a metal, and each of the upper electrode layer 312b and the lower electrode layer 312a may be a metal layer including gold (Au), copper (Cu), silver (Ag), or aluminum (Al).

The module 300 is not limited to the above-described structure and may be any module on which an interconnection structure for driving the LED 20 is formed. For example, the module 300 may have a structure in which the LED 20 is mounted on a lead frame.

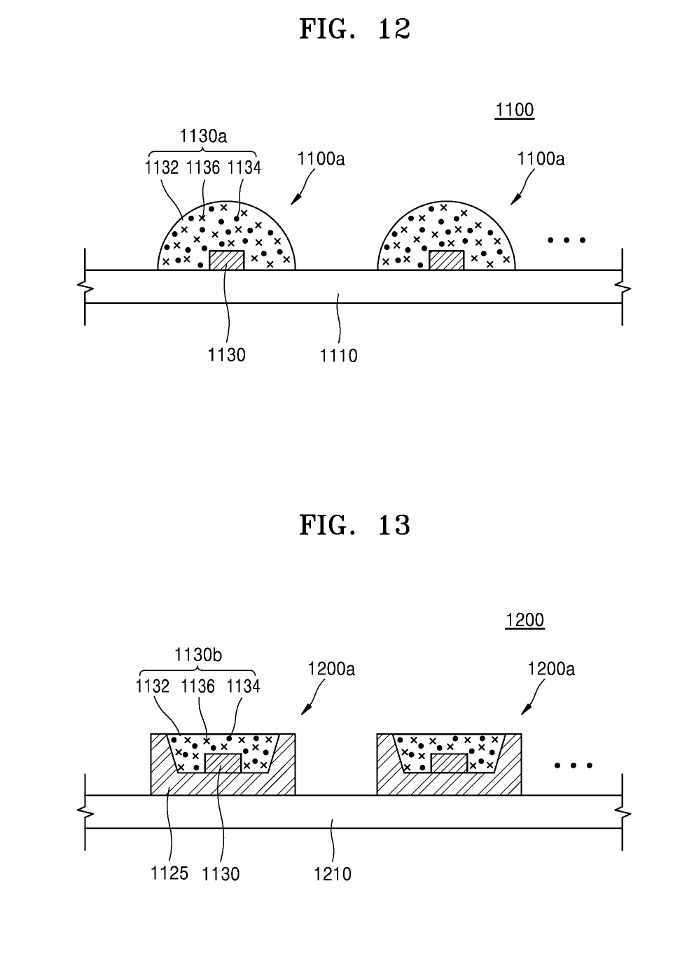

FIGS. 12 and 13 are cross-sectional views of white light source modules including an LED manufactured by a method of manufacturing an LED according to an exemplary embodiment.

Referring to FIG. 12, a light source module 1100 for a liquid crystal display (LCD) backlight may include a circuit substrate 1110 and a plurality of white light-emitting devices 1100a arranged on the circuit substrate 1110. A conductive pattern may be formed on a top surface of the circuit substrate 1110 and connected to the white light-emitting devices 1100a.

Each of the white light-emitting devices 1100a may have a structure in which an LED 1130 configured to emit blue light is directly mounted as a chip-on-board (COB) type on the circuit substrate 1100. The LED 1130 may be one of the LEDs 10 and 20 manufactured by the methods of manufacturing the LEDs according to the above-described exemplary embodiments. Each of the white light-emitting devices 1100a may include a wavelength conversion unit (or wavelength conversion layer) 1130a, which may serve as a lens and have a hemispherical shape, and have a wide beam angle. The wide beam angle of each of the white light-emitting devices 1100a may contribute toward reducing a thickness or width of an LCD.

Referring to FIG. 13, a light source module 1200 for an LCD backlight may include a circuit substrate 1210 and a plurality of white light-emitting devices 1200a arranged on the circuit substrate 1210. Each of the white light-emitting devices 1200a may include an LED 1130, which may be mounted in a reflector cup of a package main body 1125 and emit blue light, and a wavelength conversion unit 1130b configured to encapsulate the LED 1130. The LED 1130 may be one of the LEDs 10 and 20 manufactured by the methods of manufacturing the LEDs according to the above-described exemplary embodiments.

Each of the wavelength conversion units 1130a and 1130b may contain wavelength conversion materials 1132, 1134, and 1136, such as phosphor and/or quantum dots (QDs), for example. The wavelength conversion materials 1132, 1134, and 1136 will be described in detail later.

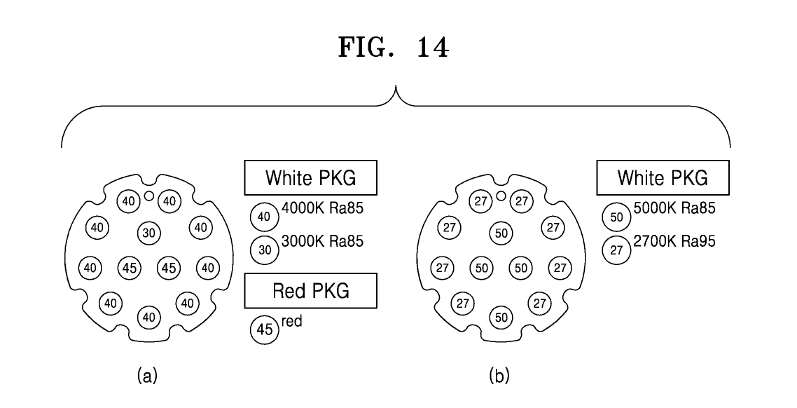

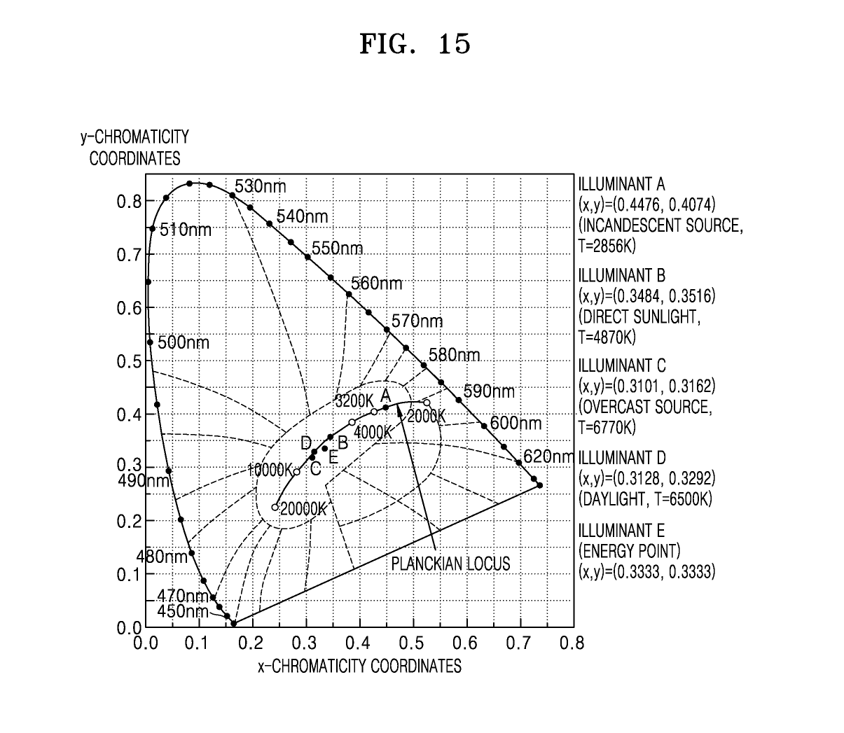

FIG. 14 is a schematic cross-sectional view of a white light source module including an LED manufactured by a method of manufacturing an LED according to an exemplary embodiment, wherein the white light source module may be applied to a lighting apparatus. FIG. 15 is an international commission on illumination (CIE) chromaticity diagram of a complete radiator spectrum that may be used for an LED manufactured by a method of manufacturing an LED according to an exemplary embodiment.

Specifically, each of light source modules shown in (a) and (b) of FIG. 14 may include a plurality of LED packages 30, 40, 45, 27, and 50 mounted on a circuit substrate. Each of the LED packages 30, 40, 45, 27, and 50 may be one of the LEDs 10 and 20 manufactured by the methods of manufacturing the LEDs according to the above-described exemplary embodiments. A plurality of LED packages mounted on one light source module may include homogenous packages configured to emit light having substantially the same wavelength or include heterogeneous packages configured to emit light having different wavelengths as in the present embodiment.

Referring to (a) of FIG. 14, a white light source module may be manufactured by combining white LED packages 40 and 30 having a color temperature of about 4,000 K and about 3,000 K with a red LED package. The white light source module may adjust a color temperature in the range of about 3,000 K to about 4,000 K and provide white light having a color rendering index (CRI) Ra ranging from about 85 to about 99.

In another exemplary embodiment, the white light source module may include only white LED packages, and some of the white LED packages may be configured to emit white light having different color temperatures. For example, referring to (b) of FIG. 14, a white light source module may be manufactured by combining a white LED package 27 having a color temperature of about 2,700 K with a white LED package 50 having a color temperature of about 5,000 K. The white light source module may adjust a color temperature in the range of about 2,700 K to about 5,000 K and provide white light having a CRI Ra of about 85 to about 99. The number of LED packages for each color temperature may be changed according to a basic color temperature setting value. For example, in a lighting apparatus, of which a basic color temperature setting value corresponds to a color temperature of about 4,000 K, the number of packages corresponding to the color temperature of about 4,000 K may be larger than the number of packages corresponding to a color temperature of about 3,000 K or the number of red LED packages.

For example, a heterogeneous package may include a blue LED, a white LED manufactured by combining yellow, green, red, or orange phosphors, and at least one of violet, blue, green, red, or infrared (IR) LEDs to control a color temperature of white light and a color rendering index (CRI).

In a single LED package, light in a desired color may be determined according to the wavelength of an LED chip, the kinds of phosphors, and a combination ratio of the phosphors. When white light is determined, a color temperature and a CRI may be controlled.

For example, when an LED chip emits blue light, an LED package including at least one of yellow, green, and red phosphors may be configured to emit white light having various color temperatures according to a combination ratio of the phosphors. Alternatively, an LED package in which a green or red phosphor is applied to the blue LED chip may be configured to emit green or red light. The LED package configured to emit white light may be combined with the LED package configured to emit green or red light to control a color temperature of white light and CRI. Also, an LED package may include at least one of LEDs configured to emit violet, blue, green, red, or IR light.

A CRI of the lighting apparatus may be controlled to be within the range of 40 (e.g., a sodium (Na) lamp) to 100 (e.g., solar light) and emit various types of white light having a color temperature range from 1500 K to 20000 K. Color of illumination light may be adjusted to an ambient atmosphere or mood by generating visible light (e.g., purple light, blue light, green light, red light, and orange light) or infrared (IR) light. Also, the lighting apparatus may generate light having a specific wavelength to stimulate plant growth.

White light generated by a combination of a blue LED with yellow, green, red phosphor and/or green and red LEDs may have at least two peak wavelengths. As shown in FIG. 15, coordinates (x, y) of the white light in a CIE 1931 coordinate system may be located on a segment connecting point A (0.4476, 0.4074), point B (0.3484, 0.3516), point C (0.3101, 0.3162), point D (0.3128, 0.3292), and point E (0.3333, 0.3333) or located in a region defined by the segment and a blackbody radiator spectrum. A color temperature of the white light may be between 1500 K and 20000 K. In FIG. 15, the white light around point E (0.3333, 0.3333) disposed under the black-body radiator spectrum (Planckian locus) is relatively weak in the light of the yellow-based component, and thus may be used as an illumination light source in a region in which a user may have a more vivid or fresh feeling than naked eyes. Therefore, an illumination product using the white light around point E (0.3333, 0.3333) disposed under the black-body radiator spectrum (Planckian locus) may be used at stores (e.g., shopping malls) that sell groceries and/or clothes.

Furthermore, various materials, such as phosphors and/or quantum dots (QDs), may be used as materials capable of converting the wavelength of light emitted by a semiconductor LED.

The phosphor may have the following empirical formulas and colors.

Oxide-based: yellow and green color Y₃Al₅O₁₂:Ce, Tb₃Al₅O₁₂:Ce, Lu₃Al₅O₁₂:Ce

Silicate-based: yellow color and green color (Ba,Sr)₂SiO₄:Eu, yellow color and orange color (Ba,Sr)₃SiO₅:Ce

Nitride-based: green color β-SiAlON:Eu, yellow color La₃Si₆O₁₁:Ce, orange color α-SiAlON:Eu, red color CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4) Formula (1)

In Formula (1), Ln may be at least one element selected from the group consisting of Group Ma elements and rare-earth elements, and M may be at least one element selected from the group consisting of calcium (Ca), barium (Ba), strontium (Sr), and magnesium (Mg).

Fluoride-based: KSF-based red color K₂SiF₆:Mn₄⁺, K₂TiF₆:Mn₄⁺, NaYF₄:Mn₄⁺, NaGdF₄:Mn₄⁺

The composition of the phosphor basically conforms with stoichiometry, and the respective elements may be substituted by other elements included in the respective groups of the periodic table. For example, strontium (Sr) may be substituted by at least one selected from the group consisting of barium (Ba), calcium (Ca), and magnesium (Mg) of alkaline-earth group II, and Y may be substituted by at least one selected from the group terbium (Tb), lutetium (Lu), scandium (Sc), and gadolinium (Gd). In addition, europium (Eu), which is an activator, may be substituted by at least one selected from the group consisting of cerium (Ce), terbium (Tb), praseodymium (Pr), erbium (Er), and ytterbium (Yb) according to a desired energy level. The activator may be applied solely or a sub-activator may be additionally applied for characteristic modification.

In particular, a fluoride-based red phosphor may be coated with a Manganese-free fluoride to improve reliability at a high temperature and a high humidity. Alternatively, the surface of the fluoride-based red phosphor or the surface of the manganese-free fluoride coating layer may be further coated with an organic material. Unlike other phosphors, the fluoride-based red phosphor may embody a relatively narrow full width at half-maximum (FWHM) of about 40 nm or less and be applied to a high-resolution television (TV), such as an ultrahigh-definition (UHD) TV.

The following Table 1 shows types of phosphors in respective fields to which a white LED using a blue LED chip (about 440 nm to about 460 nm) or a ultraviolet (UV) LED chip (about 380 nm to about 440 nm) is applied.

TABLE 1

| Purpose | Phosphor | Purpose | Phosphor |
|---|---|---|---|
| LED | β-SiAlON:Eu2+ | Side View | Lu₃Al₅O₁₂:Ce3+ |
| TV BLU | (Ca, Sr)AlSiN₃:Eu2+ | (Mobile, | Ca-α-SiAlON:Eu2+ |
| | La₃Si₆N₁₁:Ce3+ | Note PC) | La₃Si₆N₁₁:Ce3+ |
| | K₂SiF₆:Mn4+ | | (Ca, Sr)AlSiN₃:Eu2+ |
| | SrLiAl3N4:Eu | | Y₃Al₅O₁₂:Ce3+ |
| | Ln₄₋ₓ(Eu_{z}M_{1-z})ₓSi_{12-y}Al_{y}O_{3+x+y}N_{18-x-y} | | (Sr, Ba, Ca, Mg)2SiO4:Eu2+ |
| | (0.5 ≦ x ≦ 3, 0 < z < 0.3, 0 < y ≦ 4) | | K₂SiF₆:Mn4+ |
| | K2TiF6:Mn4+ | | SrLiAl3N4:Eu |
| | NaYF4:Mn4+ | | Ln₄₋ₓ(Eu_{z}M_{1-z})ₓSi_{12-y}Al_{y}O_{3+x+y}N_{18-x-y} |
| | NaGdF4:Mn4+ | | (0.5 ≦ x ≦ 3, 0 < z < 0.3, 0 < y ≦ 4) |
| | | | K2TiF6:Mn4+ |
| | | | NaYF4:Mn4+ |
| | | | NaGdF4:Mn4+ |
| Illumination | Lu₃Al₅O₁₂:Ce3+ | Interior | Lu₃Al₅O₁₂:Ce3+ |
| | Ca-α-SiAlON:Eu2+ | (Head | Ca-α-SiAlON:Eu2+ |
| | La₃Si₆N₁₁:Ce3+ | Lamp, etc.) | La₃Si₆N₁₁:Ce3+ |
| | (Ca, Sr)AlSiN₃:Eu2+ | | (Ca, Sr)AlSiN₃:Eu2+ |
| | Y₃Al₅O₁₂:Ce3+ | | Y₃Al₅O₁₂:Ce3+ |
| | K₂SiF₆:Mn4+ | | K₂SiF₆:Mn4+ |
| | SrLiAl3N4:Eu | | SrLiAl3N4:Eu |
| | Ln₄₋ₓ(Eu_{z}M_{1-z})ₓSi_{12-y}Al_{y}O_{3+x+y}N_{18-x-y} | | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) | | (0.5 ≦ x ≦ 3, 0 < z < 0.3, 0 < y ≦ 4) |
| | K2TiF6:Mn4+ | | K2TiF6:Mn4+ |
| | NaYF4:Mn4+ | | NaYF4:Mn4+ |
| | NaGdF4:Mn4+ | | NaGdF4:Mn4+ |

In addition, wavelength conversion materials, such as QDs, may be used for a wavelength conversion unit and may be used in replacement of or in combination with the phosphors.

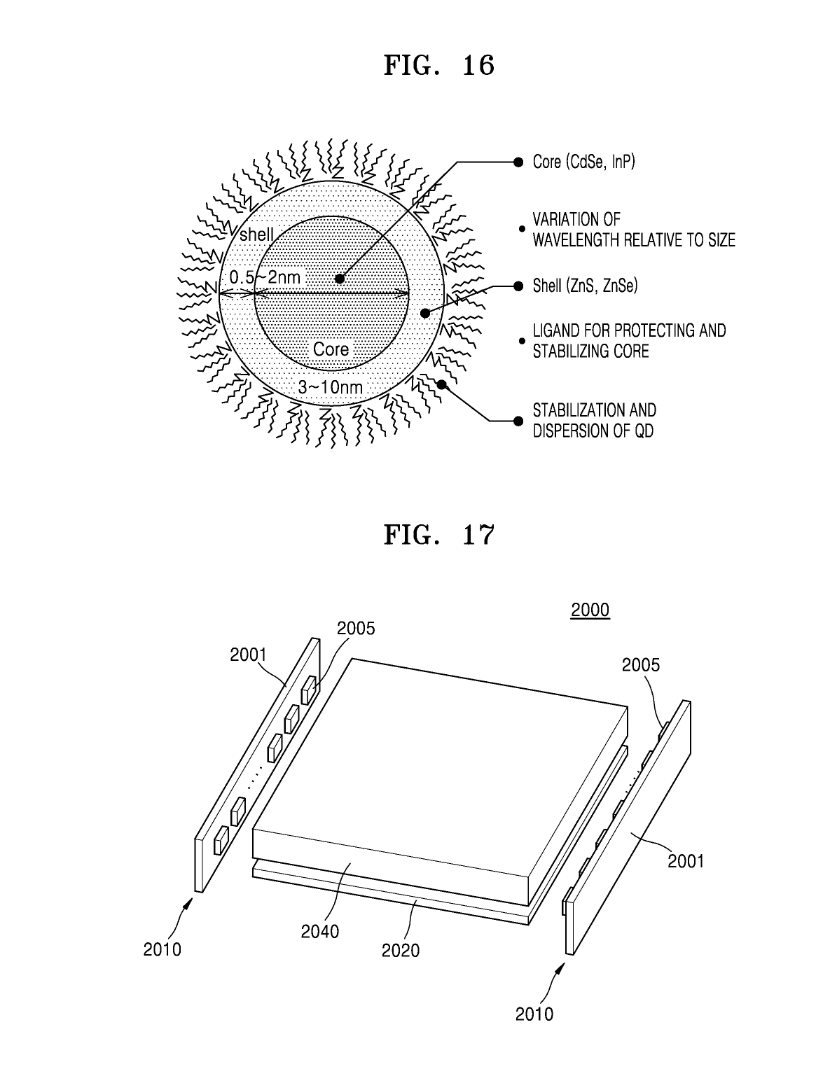

FIG. 16 is a schematic diagram showing a sectional structure of a quantum dot (QD) that may be used as a wavelength conversion material for an LED manufactured by a method of manufacturing an LED according to an exemplary embodiment.

Specifically, a QD may have a core-shell structure by using a Group III-V compound semiconductor or a Group II-VI compound semiconductor. For example, the QD may include a core, such as CdSe or InP, and a shell, such as ZnS and ZnSe. Also, the QD may include a ligand for stabilizing the core and the shell. For example, the core may have a diameter of about 1 nm to about 30 nm, and specifically, about 3 nm to about 10 nm. The shell may have a thickness of about 0.1 nm to about 20 nm, and specifically, about 0.5 nm to about 2 nm.

The QD may be provided in various colors according to a size. In particular, when the QD is used in replacement of phosphors, the QD may be used as a red phosphor or a green phosphor. When the QD is used, a narrower full width at half-maximum (FWHM) may be provided.

The wavelength conversion material may be contained in an encapsulant. Alternatively, the wavelength conversion material may be formed as a film type and bonded to a surface of an optical structure, such as an LED chip or a light guide plate (LGP). In this case, the wavelength conversion material may have a uniform structure and be easily applied to a desired region.

FIG. 17 is a schematic perspective view of a backlight unit (BLU) 2000 including an LED manufactured by a method of manufacturing an LED according to an exemplary embodiment.

Specifically, the BLU 2000 may include an LGP 2040 and light source modules 2010 provided on two side surfaces of the LGP 2040. Also, the BLU 2000 may further include a reflection plate 2020 located under the LGP 2040. In the present embodiment, the BLU 2000 may be an edge-type BLU. In some exemplary embodiments, the light source module 2010 may be provided on only one side surface of the LGP 2040 or additionally provided on another side surface of the LGP 2040. The light source module 2010 may include a printed circuit board (PCB) 2001 and a plurality of light sources 2005 mounted on a top surface of the PCB 2001. The light source 2005 may be one of the LEDs 10 and 20 manufactured by the methods of manufacturing the LEDs according to the above-described exemplary embodiments.

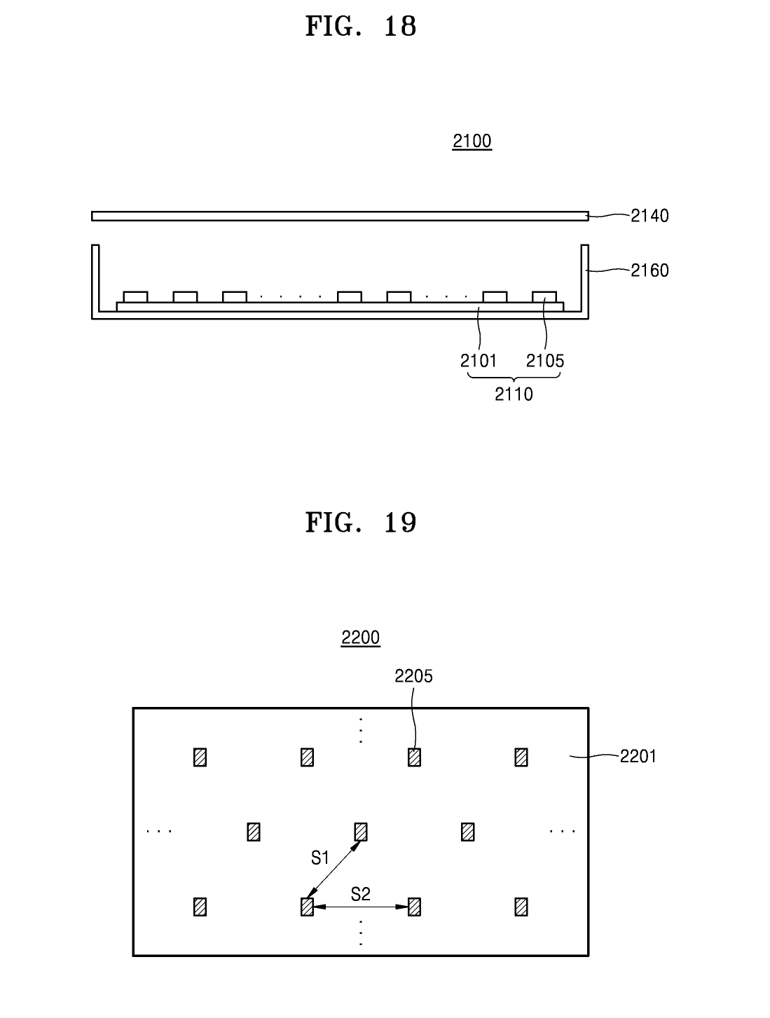

FIG. 18 is a diagram of a direct-light-type BLU 2100 including an LED manufactured by a method of manufacturing an LED according to an exemplary embodiment.

Specifically, the BLU 2100 may include an optical diffusion plate 2140 and a light source module 2110 arranged under the optical diffusion plate 2140. Also, the BLU 2100 may further include a bottom case 2160, which may be located under the optical diffusion plate 2140 and contain the light source module 2110. In the present embodiment, the BLU 2100 may be a direct-light-type BLU.

The light source module 2110 may include a PCB 2101 and a plurality of light sources 2105 mounted on a top surface of the PCB 2101. The light source 2105 may be one of the LEDs 10 and 20 manufactured by the methods of manufacturing the LEDs according to the above-described exemplary embodiments.

FIG. 19 is a diagram of a BLU including an LED manufactured by a method of manufacturing an LED according to an exemplary embodiment.

Specifically, FIG. 19 illustrates an example in which a light source 2205 is located in a direct-light-type BLU 2200. The light source 2205 may be one of the LEDs 10 and 20 manufactured by the methods of manufacturing the LEDs according to the above-described exemplary embodiments.

The direct-light-type BLU 2200 according to the present embodiment may include a plurality of light sources 2205 arranged on a substrate 2201. The light sources 2205 may be arranged as a matrix type in rows and columns, which may be arranged in a zigzag fashion. A first matrix, in which a plurality of light sources 2205 are arranged in rows and columns, may be arranged to be overlapped with a second matrix having the same shape as the second matrix. Thus, it may be interpreted that each of light sources 2205 included in the second matrix is located within a quadrangle formed by four adjacent light sources 2205 included in the first matrix.

The above configuration is only an example and, to improve luminance uniformity and optical efficiency of the direct-light-type BLU, the first and second matrices may have different arrangement structures and intervals. Also, in addition to a method of arranging a plurality of light sources, distances Si and S2 between adjacent light sources may be determined to ensure luminance uniformity. Thus, since row and columns including the light sources 2205 are arranged in a zigzag fashion, the number of light sources 2205 may be reduced by as much as about 15% to 25% for the same size of a light emission area.

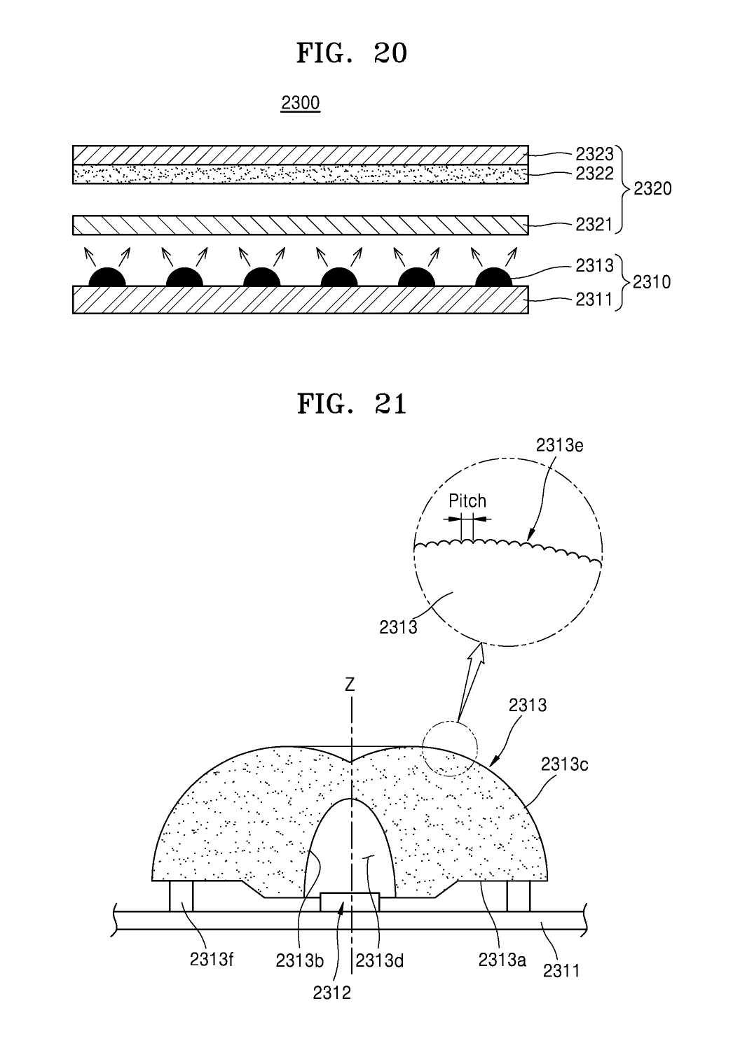

FIG. 20 is a diagram of a direct-light-type BLU 2300 including an LED manufactured by a method of manufacturing an LED, according to an exemplary embodiment, and FIG. 21 is an enlarged view of a light source module 2310 of FIG. 20.

Specifically, the BLU 2300 according to the present embodiment may include an optical sheet 2320 and the light source module 2310 arranged under the optical sheet 2320. The optical sheet 2320 may include a diffuser sheet 2321, a condenser sheet 2322, and a protection sheet 2323.

The light source module 2310 may include a circuit substrate 2311, a plurality of light sources 2312 mounted on the circuit substrate 2311, and a plurality of optical devices 2313 located on the plurality of light sources 2312, respectively. The light source 2312 may be one of the LEDs 10 and 20 manufactured by the methods of manufacturing the LEDs according to the above-described exemplary embodiments.

Each of the optical devices 2313 may control a beam angle of light through refraction. In particular, an optical beam angle lens configured to diffuse light emitted by the light source 2312 toward a wide region may be used as each of the optical devices 2313. Since the light source 2312 to which the optical device 2313 is adhered to has a wide light distribution, when the light source module 2310 is used for a backlight unit (BLU) or a flat-panel lighting apparatus, the number of the light sources 2312 arranged on the same size of an area may be reduced.

As shown in FIG. 21, the optical device 2313 may include a bottom surface 2313a at least a part of which is located on the light source 2312, an incidence surface 2313b to which light emitted by the light source 2312 is incident, and an emission surface 2313c from which light is externally emitted. The bottom surface 2313a may include a groove unit 2313d, which may be depressed toward the emission surface 2313c in the center of the bottom surface 2313a through which an optical axis Z of the light source 2312 passes. A surface of the groove unit 2313d may be defined by the incidence surface 2313b to which light emitted by the light source 2312 is incident. That is, the incidence surface 2313b may be included in the surface of the groove unit 2313d.

Since a central region of the bottom surface 2313a, which is connected to the incidence surface 2313b, partially protrudes, the bottom surface 2313a may have a generally non-flat-panel structure. That is, unlike a typical bottom surface having a generally flat structure, the bottom surface 2313a may partially protrude along the circumference of the groove unit 2313d. The bottom surface 2313a may be connected with a plurality of support units 2313f. When the optical device 2313 is mounted on the circuit substrate 2311, the plurality of support units 2313f may fix and support the optical device 2313.

The emission surface 2313c may form a dome shape and protrude upwardly (or in a light emission direction) from an edge of the optical device 2313 connected to the bottom surface 2313a. A center of the emission surface 2313c through which the optical axis Z passes may be depressed toward the groove unit 2313d and have a point of inflection. A plurality of rough units 2313e may be periodically arranged on the emission surface 2313c from the optical axis Z toward the edge of the optical device 2313. The plurality of rough units 2313e may have ring shapes corresponding to a horizontal sectional shape of the optical device 2313 and form concentric circles about the optical axis Z. The plurality of rough units 2313e may form a periodical pattern and radially spread along the emission surface 2313c about the optical axis Z.

The plurality of rough units 2313e may be spaced apart from one another at predetermined pitches and form a pattern. In this case, a pitch between the plurality of rough units 2313e may range from about 0.01 mm to about 0.04 mm. The plurality of rough units 2313e may compensate for differences in performance between the optical devices 2313 due to minute processing errors that may occur during a process of manufacturing the optical devices 2313. Thus, uniformity of light distribution may be improved.

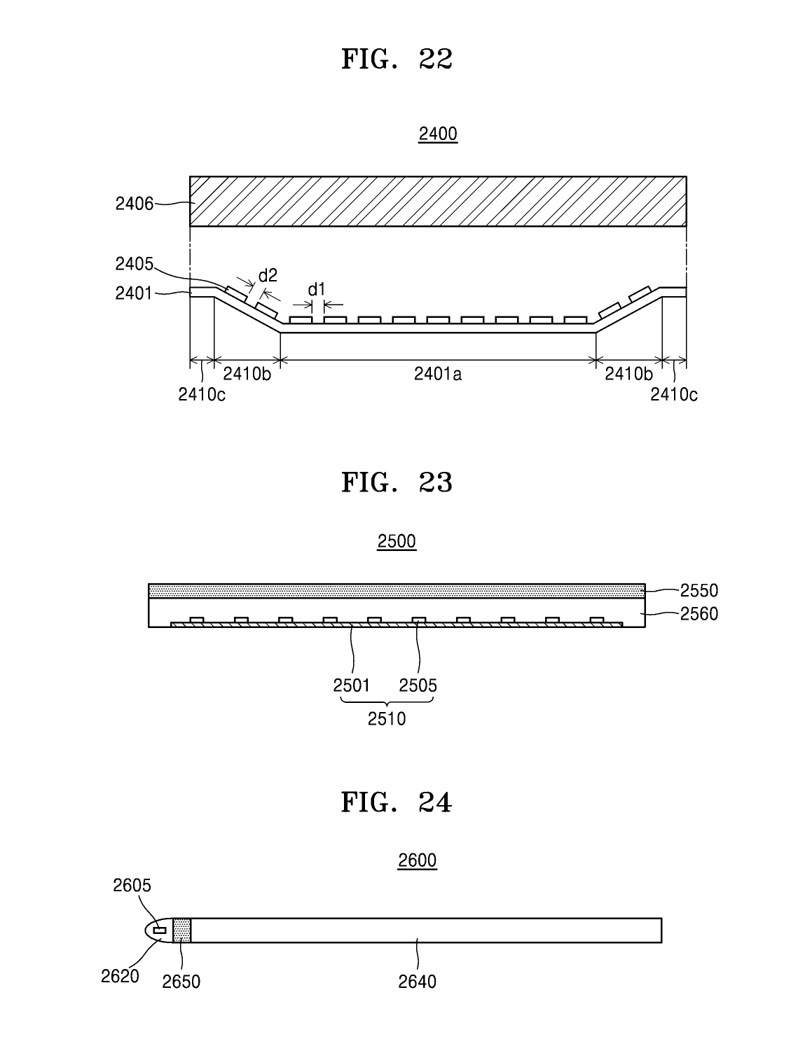

FIG. 22 is a diagram of a direct-light-type BLU 2400 including an LED manufactured by a method of manufacturing an LED according to an exemplary embodiment.

Specifically, the BLU 2400 may include a light source 2405 mounted on a circuit substrate 2401 and at least one optical sheet 2406 located above the light source 2405. The light source 2405 may be a white light-emitting device containing a red phosphor. The light source 2405 may be a module mounted on the circuit substrate 2401. The light source 2405 may be one of the LEDs 10 and 20 manufactured by the methods of manufacturing the LEDs according to the above-described exemplary embodiments.

The circuit substrate 2401 according to the present embodiment may include a first plane portion 2401a corresponding to a main region, an inclined portion 2401b located around the first plane portion 2401a, and a second plane portion 2401c located at a corner of the circuit substrate 2401 outside the inclined portion 2401b. At least a portion of the inclined portion 2401b may be bent. The light sources 2405 may be arranged at intervals of a first distance d1 on the first plane portion 2401a. At least one light source 2405 may be arranged at intervals of a second distance d2 on the inclined portion 2401b. The first distance d1 may be equal to the second distance d2. A width (or length in a sectional view) of the inclined portion 2401b may be less than a width of the first plane portion 2401a or greater than a width of the second plane portion 2401c. Also, at least one light source 2405 may be arranged on the second plane portion 2401c depending on an embodiment.

An inclination of the inclined portion 2401b with respect to the first plane portion 2401a may be appropriately controlled within a range of between about 0° to about 90°. The circuit substrate 2401 may adopt the above-described structure and maintain uniform brightness around the edge of the optical sheet 2406.

FIGS. 23 to 25 are diagrams of BLUs 2500, 2600, and 2700 including LEDs manufactured by a method of manufacturing an LED according to an exemplary embodiment.

Specifically, wavelength conversion units 2550, 2650, and 2750 may not be located in light sources 2505, 2605, and 2705 but in the BLUs 2500, 2600, and 2700 outside the light sources 2505, 2605, and 2705 so that the BLUs 2500, 2600, and 2700 may convert light from the light sources 2505, 2606, and 2705. Each of the light sources 2505, 2605, and 2705 may be one of the LEDs 10 and 20 manufactured by the methods of manufacturing the LEDs according to the above-described exemplary embodiments.

The BLU 2500 of FIG. 23 may be a direct-light-type BLU and include the wavelength conversion unit 2550, the light source module 2510 arranged under the wavelength conversion unit 2550, and a bottom case 2560 configured to contain the light source module 2510. Also, the light source module 2510 may include a PCB 2501 and a plurality of light sources 2505 mounted on a surface of the PCB 2501.

In the BLU 2500, the wavelength conversion unit 2550 may be located on the bottom case 2560. Accordingly, the wavelength of at least part of light emitted by the light source module 2510 may be converted by the wavelength conversion unit 2550. The wavelength conversion unit 2550 may be manufactured and applied as an additional film or integrated with an optical diffuser plate (not shown).

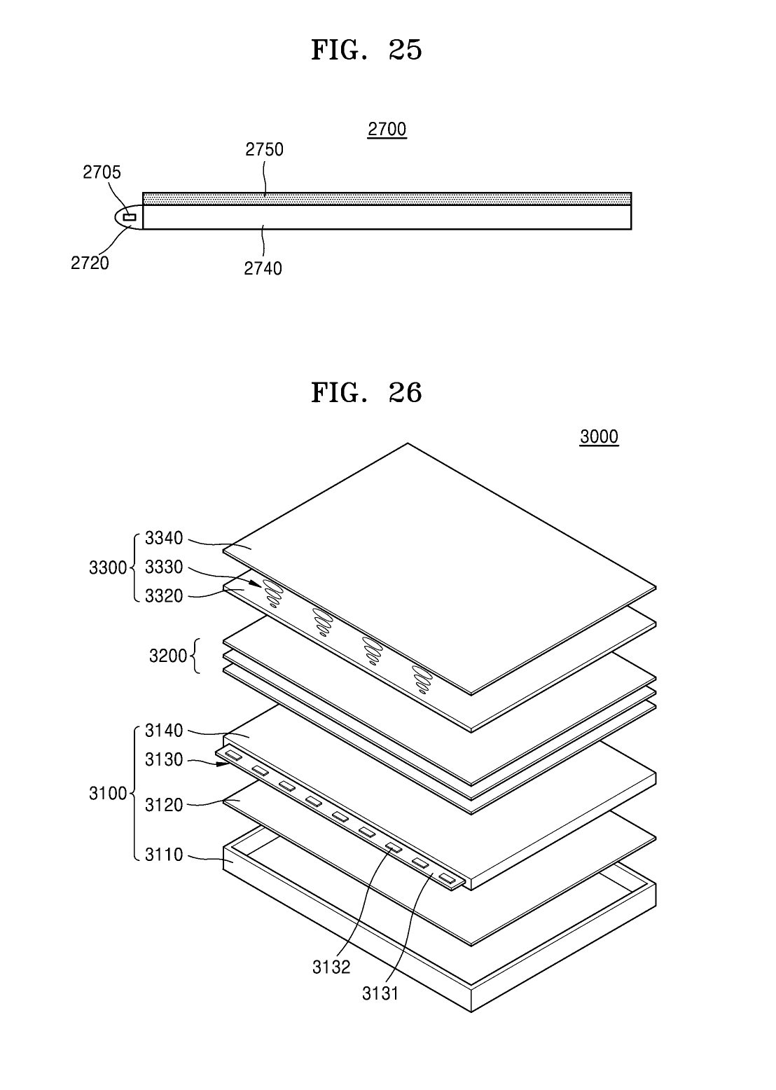

The BLUs 2600 and 2700 of FIGS. 24 and 25 may be edge-type BLUs and include wavelength conversion units 2650 and 2750, LGPs 2640 and 2740, and reflection units 2620 and 2720 located on one sides of the LGPs 2640 and 2740, and light sources 2605 and 2705, respectively. Light emitted by the light sources 2605 and 2705 may be guided by the reflection units 2620 and 2720 into the LGPs 2640 and 2740, respectively. In the BLU 2600 of FIG. 24, the wavelength conversion unit 2650 may be located between the LGP 2640 and the light source 2605. In the BLU 2700 of FIG. 25, the wavelength conversion unit 2750 may be located on a light emission surface of the LGP 2740.

The wavelength conversion units 2550, 2650, and 2750 may include phosphors. In particular, QD phosphors may be used in the wavelength conversion units 2550, 2650, and 2750 to make up for characteristics of QDs that are vulnerable to heat or moisture applied by a light source.

FIG. 26 is a schematic exploded perspective view of a display apparatus 3000 including an LED manufactured by a method of manufacturing an LED according to an exemplary embodiment.

Specifically, the display apparatus 3000 may include a BLU 3100, an optical sheet 3200, and an image display panel (e.g., a liquid crystal (LC) panel) 3300. The BLU 3100 may include a bottom case 3110, a reflection plate 3120, an LGP 3140, and a light source module 3130 provided on at least one side surface of the LGP 3140. The light source module 3130 may include a PCB 3131 and a light source 3132.

In particular, the light source 3132 may be a side-view-type LED mounted on a side surface of the LGP 3140 adjacent to a light emission surface. The light source 3132 may be one of the LEDs 10 and 20 manufactured by the methods of manufacturing the LEDs according to the above-described exemplary embodiments. The light source 3132 may include various kinds of sheets, such as a prism sheet or a protection sheet.

The image display panel 3300 may display an image by using light emitted by the optical sheet 3200. The image display panel 3300 may include an array substrate 3320, an LC layer 3330, and a color filter substrate 3340. The array substrate 3320 may include pixel electrodes arranged in a matrix shape, thin-film transistors (TFTs) configured to apply a driving voltage to the pixel electrodes, and signal lines configured to operate the TFTs.

The color filter substrate 3340 may include a transparent substrate, a color filter, and a common electrode. The color filter may include filters configured to selectively transmit light having a specific wavelength among white light emitted by the BLU 3100. The LC layer 3330 may be rearranged due to an electric field formed between the pixel electrode and the common electrode and control a light transmittance of light. The light of which the light transmittance is controlled may be transmitted through the color filter of the color filter substrate 3340 and display an image. The image display panel 3300 may further include a driver circuit unit (or driver circuit) configured to process an image signal.

Since the display apparatus 3000 according to the present embodiment uses the light source 3132 configured to emit blue light, green light, and red light having relatively narrow FWHMs, after the emitted light is transmitted through the color filter substrate 3340, blue, green and red colors having high color purities may be provided.

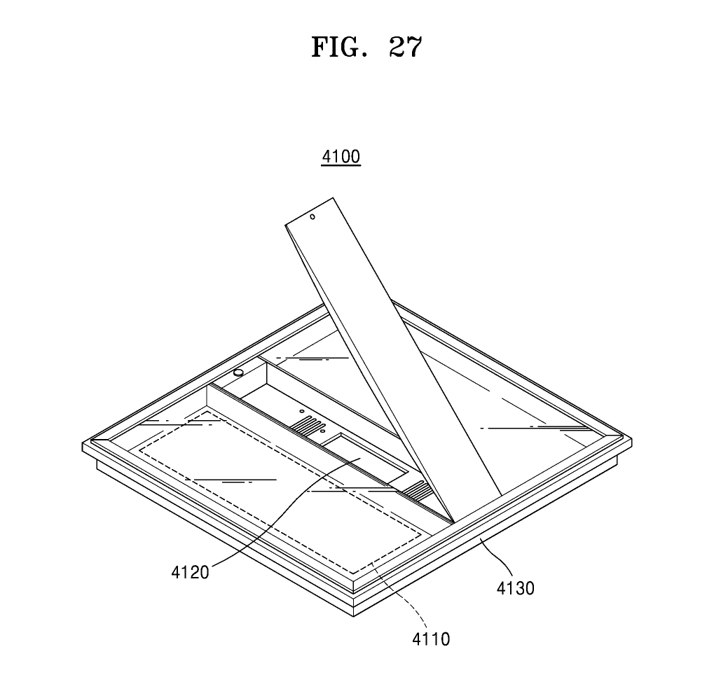

FIG. 27 is a schematic perspective view of a flat-panel lighting apparatus 4100 including an LED manufactured by a method of manufacturing an LED according to an exemplary embodiment.

Specifically, the flat-panel lighting apparatus 4100 may include a light source module 4110, a power supply device 4120, and a housing 4030. The light source module 4110 may include an LED array that serves as a light source. The light source module 4110 may include a light source, which is one of the LEDs 10 and 20 manufactured by the methods of manufacturing the LEDs according to the above-described exemplary embodiments. The power supply device 4120 may include an LED driver.

The light source module 4110 may include an LED array and have a generally planar shape. The LED array may include an LED and a controller configured to store driving information of the LED.

The power supply device 4120 may be configured to supply power to the light source module 4110. The housing 4130 may form a space to contain the light source module 4110 and the power supply device 4120 and have a hexahedral shape having one open side surface, but the inventive concept is not limited thereto. The light source module 4110 may be located to emit light through the open side surface of the housing 4130.

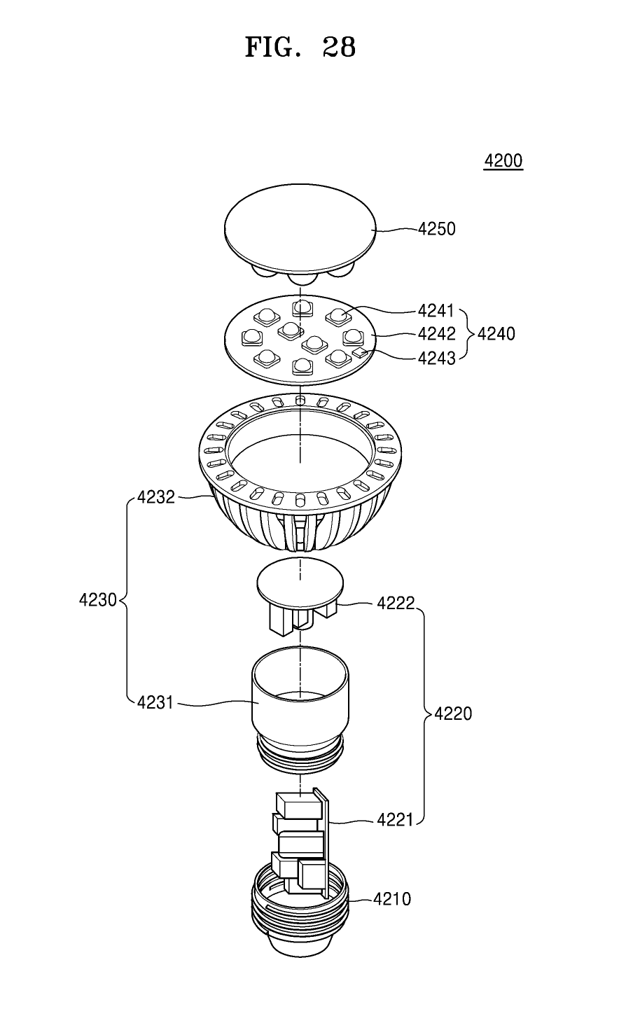

FIG. 28 is a schematic exploded perspective view of a lighting apparatus 4200 including an LED manufactured by a method of manufacturing an LED according to an exemplary embodiment.

Specifically, the lighting apparatus 4200 may include a socket 4210, a power source unit 4220, a radiation unit 4230, a light source module 4240, and an optical unit 4250. The light source module 4240 may include an LED array, and the power source unit 4220 may include an LED driver.

The socket 4210 may be configured to be capable of replacing a socket of a lighting apparatus of the related art. Power supplied to the lighting apparatus 4200 may be applied through the socket 4210. As shown in FIG. 28, the power supply unit 4220 may include a first power supply unit 4221 and a second power supply unit 4222. The radiation unit 4230 may include an internal radiation unit 4231 and an external radiation unit 4232. The internal radiation unit 4131 may be directly connected to the light source module 4240 and/or the power source unit 4220 so that heat may be transmitted to the external radiation unit 4232. The optical unit 4250 may include an internal optical unit (not shown) and an external optical unit (not shown) and may be configured to uniformly disperse light emitted by the light source 4240.

The light source module 4240 may receive power from the power source unit 4220 and emit light to the optical unit 4250. The light source module 4240 may include at least one LED package 4241, a circuit substrate 4242, and a controller 4243. The controller 4243 may store driving information regarding the LED package 4241. The LED package 4241 may include one of the LEDs 10 and 20 manufactured by the methods of manufacturing the LEDs according to the above-described exemplary embodiments.

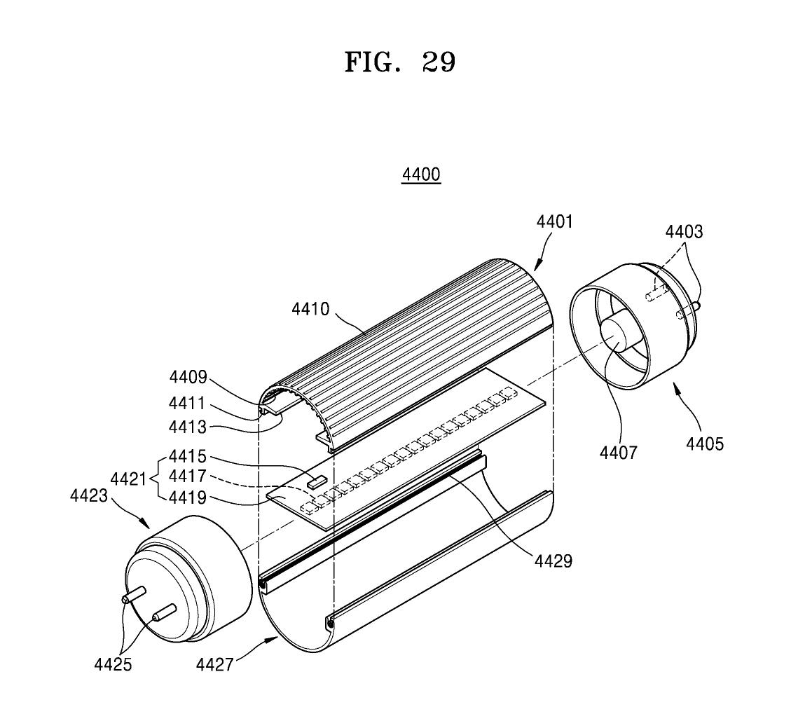

FIG. 29 is a schematic exploded perspective view of a bar-type lighting apparatus 4400 including an LED manufactured by a method of manufacturing an LED according to an exemplary embodiment.

Specifically, the lighting apparatus 4400 may include a radiation member 4401, a cover 4427, a light source module 4421, a first socket 4405, and a second socket 4423. A plurality of radiation pins (e.g., radiation pins 4409 and 4410) may be formed on an inner surface of the radiation member 4401 and/or on an outer surface of the radiation member 4401. The radiation pins 4409 and 4410 may be designed to have various shapes and intervals therebetween. A support 4413 having a protruding shape may be formed inside the radiation member 4401. The light source module 4421 may be fixed to the support 4413. Clasps 4411 may be formed at two end portions of the radiation member 4401.

Clasp grooves 4429 may be formed in the cover 4427. The clasps 4411 of the radiation member 4401 may be hook-coupled to the clasp grooves 4429. Positions of the clasp grooves 4429 and the clasp 4411 may be interchangeable.

The light source module 4421 may include an LED array. The light source module 4421 may include a PCB 4419, a light source 4417, and a controller 4415. The controller 4415 may store driving information regarding the light source 4417. Circuit interconnections for operating the light source 4417 may be formed on the PCB 4419. Also, elements to operate the light source 4417 may be formed on the PCB 4419. The light source 4417 may include one of the LEDs 10 and 20 manufactured by the methods of manufacturing the LEDs according to the above-described exemplary embodiments.

The first and second sockets 4405 and 4423, which are a pair of sockets, may be coupled with two ends of a cylindrical cover unit including the radiation member 4401 and the cover 4427. For example, the first socket 4405 may include an electrode terminal 4403 and a power supply device 4407, and the second socket 4423 may include a dummy terminal 4425. In addition, an optical sensor and/or a communication module may be embedded in any one of the first socket 4405 or the second socket 4423. For example, the optical sensor and/or the communication module may be embedded in the second socket 4423 including the dummy terminal 4425. In another example, the optical sensor and/or the communication module may be embedded in the first socket 4405 including the electrode terminal 4403.

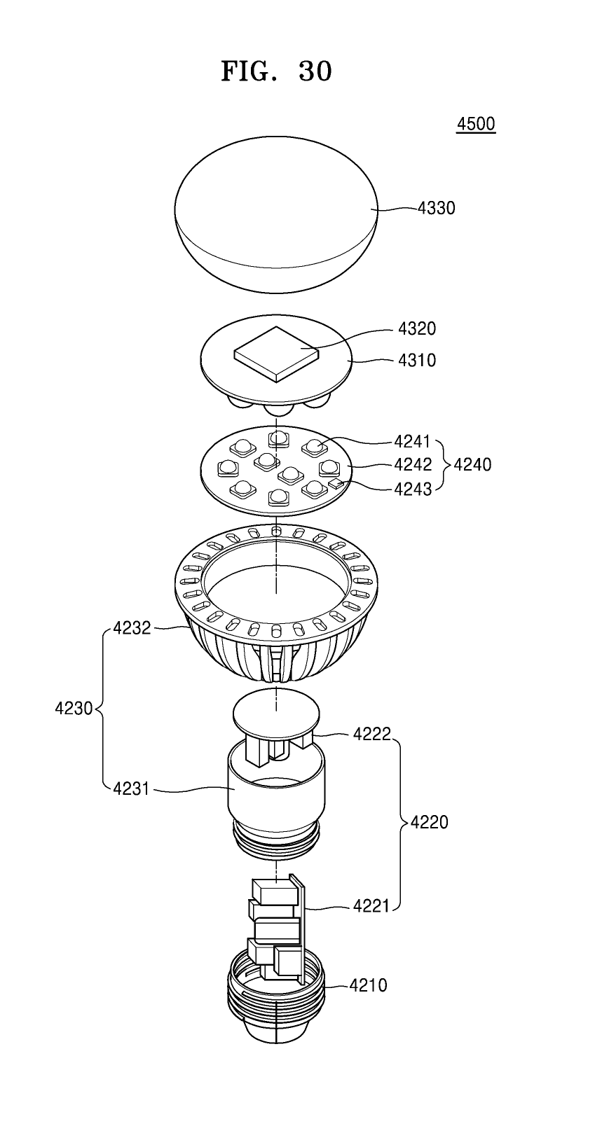

FIG. 30 is a schematic exploded perspective view of a lighting apparatus 4500 including an LED manufactured by a method of manufacturing an LED according to an exemplary embodiment.

Specifically, the lighting apparatus 4500 according to the present embodiment may differ from the lighting apparatus 4200 of FIG. 28 in that a reflection plate 4310 and a communication module 4320 are located on a light source module 4240. The reflection plate 4310 may be configured to uniformly disperse light, emitted by the light source module 4240, in a sideward and/or backward direction and reduce dazzle of light.

The communication 4320 may be mounted on the reflection plate 4310, and home-network communications may be enabled via the communication module 4320. For example, the communication module 4320 may be a wireless communication module using Zigbee®, wireless fidelity (WiFi), or light fidelity (LiFi), and control household illumination (e.g., turning-on/off of a lighting apparatus and control of brightness) by using a smartphone or a wireless controller. Also, electronic appliances (e.g. TVs, refrigerators, air-conditioners, door locks, and automobiles) installed inside and/or outside houses and automobile systems may be controlled by a LiFi communication module using the wavelength of visible light of lighting apparatuses installed inside and/or outside the houses. The reflection plate 4310 and the communication module 4320 may be covered with a cover unit 4330.

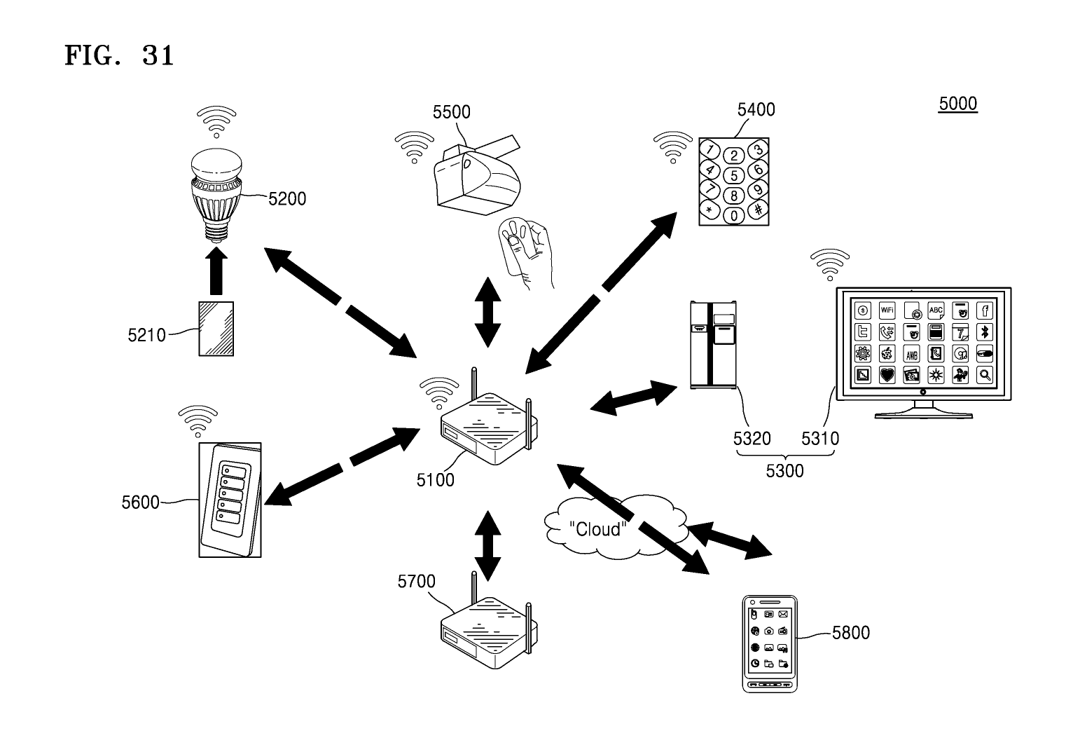

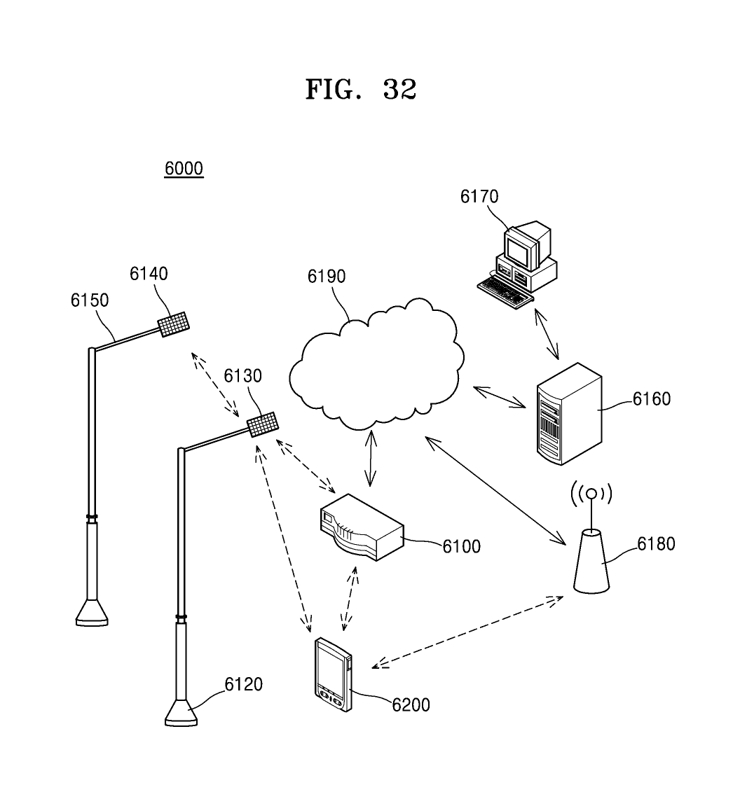

FIG. 31 is a schematic diagram of an indoor illumination control network system including an LED manufactured by a method of manufacturing an LED according to an exemplary embodiment.

Specifically, the network system 5000 may be a complex smart illumination-network system in which illumination technology using an LED (e.g., an LED lamp), Internet of Things (IoT) technology, and wireless communication technology are converged. The network system 5000 may be provided by using various lighting apparatuses and wired and/or wireless communication apparatuses. The network system 5000 may be provided by software for controlling, maintaining, and managing a sensor, a controller, a communication unit, and a network.

The network system 5000 may be applied not only to closed spaces (e.g., houses and offices) defined in buildings but also to open spaces (e.g., parks and streets). The network system 5000 may be provided based on the IoT environment and collect and process various pieces of information and provide the information to users.

The network system 5000 may include a gateway 5100, an LED lamp 5200, and a plurality of apparatuses 5300 to 5800. The LED lamp 5200 included in the network system 5000 may receive information regarding ambient environments from the gateway 5100 and control illumination of the LED lamp 5200. Also, the LED lamp 5200 may determine operation states of the plurality of apparatuses 5300 to 5800 included in the IoT environment and control the plurality of apparatuses 5300 to 5800 based on a visible light communication function of the LED lamp 5200. The LED lamp 5200 may include one of the LEDs 10 and 20 manufactured by the methods of manufacturing the LEDs according to the above-described exemplary embodiments.

The gateway 5100 may be configured to process data that are transmitted and received according to different communication protocols. The LED lamp 5200 may be connected to the gateway 5100 to be capable of communicating with the gateway 5100 and include an LED. The plurality of apparatuses 5300 to 5800 may be connected to the gateway 5100 to be capable of communicating with the gateway 5100 by various wireless communication methods. To embody the network system 5000 based on an IoT environment, each of the LED lamp 5200 and the apparatuses 5300 to 5800 may include at least one communication module. In an exemplary embodiment, the LED lamp 5200 may be connected to the gateway 5100 to be capable of communicating with the gateway 5100 by using a communication protocol (e.g., WiFi, ZigBee®, LiFi, etc.). To this end, the LED lamp 5200 may have at least one lamp communication module 5210.

The network system 5000 may be applied not only to closed spaces, such as houses or offices, but also to open spaces, such as streets or parks. When the network system 5000 is applied to a house, the network system 5000 may include a plurality of apparatuses 5300 to 5800, which may be connected to the gateway 5100 to be capable of communicating with the gateway 5100 based on IoT technology. The plurality of apparatuses 5300 to 5800 may include, for example, household appliances 5300 (e.g., a refrigerator 5320 and a personal computer (PC) 5310), a digital door lock 5400, a garage door lock 5500, a lighting switch 5600 installed on a wall, a router 5700 configured to relay wireless communication networks, and a mobile device 5800 (e.g., a smartphone, a tablet PC, or a laptop computer).

In the network system 5000, the LED lamp 5200 may determine operation states of various apparatuses 5300 to 5800 or automatically control the brightness of the LED lamp 5200 depending on ambient environments and/or statuses by using household wireless communication networks (e.g., Zigbee®, WiFi, LiFi, etc.). Also, the apparatuses 5300 to 5800 included in the network system 5000 may be controlled by using LiFi communication using visible light emitted by the LED lamp 5200.

Initially, the network system 5000 may automatically control the brightness of the LED lamp 5200 based on circumferential environments transmitted from the gateway 5100 through the lamp communication module 5210 and/or circumferential environment information collected by a sensor mounted on the LED lamp 5200. For example, the brightness of the LED lamp 5200 may be automatically controlled depending on the type of a TV program broadcasted on a TV 5310 or the brightness of a screen of the TV 5310. To this end, the LED lamp 5200 may receive operation information of the TV 5310 from the lamp communication module 5210 connected to the gateway 5100. The lamp communication module 5210 may be combined with a sensor and/or a controller included in the LED lamp 5200 to form a module.

For example, when a program type of a TV program broadcasted on the TV 5310 is a drama, the LED lamp 5200 may lower a color temperature to 12,000 K or less (e.g., 5,000 K) and adjust a color sense according to a preset value, to provide a cozy atmosphere. On the other hand, when a program type of the TV program is a comedy, the network system 5000 may be configured such that the LED lamp 5200 may increase a color temperature to 5,000 K or more according to a set value to provide bluish white light.

When there is no human being present in the home and a predetermined time has elapsed after the digital door lock 5400 is locked, all the turned-on LED lamps 5200 at home may be turned to prevent waste of electricity. Alternatively, when a security mode is set by the mobile device 5800 and the digital door lock 5400 is locked while there is no human being in the home, the LED lamp 5200 may remain turned on.

An operation of the LED lamp 5200 may be controlled depending on ambient environments collected by various sensors connected to the network system 5000. For example, when the network system 5000 is provided in a building, elements such as lamps, position sensors, and a communication module may be combined in the building and position information of people in the building may be collected. Thus, the lamps may be turned on or off based on the position information or the collected information may be provided in real-time to be used for management of facilities or efficient utilization of idle spaces. In general, since lighting apparatuses (e.g., the LED lamp 5200) are located in almost all of spaces in each floor in the building, various pieces of information in the building may be collected by a sensor combined with the LED lamp 5200 and used to manage facilities and utilize idle spaces.

In addition, the LED lamp 5200, an image sensor, a storage device, and the lamp communication module 5210 may be combined into a device, and the device may be utilized to maintain the security of the building or sense and handle emergency situations. For example, when a smoke sensor or temperature sensor is attached to the LED lamp 5200, damage by a fire may be minimized by immediately detecting that the fire has occurred. Furthermore, the brightness of a lamp may be controlled based on weather conditions and/or an amount of sunshine to save energy and provide conformable lighting environments.

As described above, the network system 5000 may be applied not only to closed spaces, such as houses, offices, or buildings, but also to open spaces, such as streets or parks. When the network system 5000 is applied to a very wide open space, it may be relatively difficult to provide the network system 5000 due to a distance limit of wireless communication and communication interference caused by various obstacles. By mounting a sensor and a communication module on each illumination mechanism and using each illumination mechanism as an information collecting unit and a communication relay unit, the network system 500 may be efficiently provided in open environments.

FIG. 32 is a schematic diagram of a network system 6000 including an LED manufactured by a method of manufacturing an LED according to an exemplary embodiment.

Specifically, FIG. 32 illustrates the network system 6000 applied to an open space, according to an exemplary embodiment. The network system 6000 according to the present embodiment may include a communication connection device 6100, a plurality of illumination mechanisms (e.g., illumination mechanisms 6120 and 6150) installed at a predetermined interval and connected to the communication connection device 6100 to be capable of communicating with the communication connection device 6100, a server 6160, a computer 6170 configured to manage the server 6160, a communication base station 6180, a communication network 6190 configured to connect the above-described apparatuses capable of communicating with one another, and a mobile device 6200.

The illumination mechanisms 6120 and 6150 installed in an external open space, such as a street or a park, may include smart engines 6130 and 6140, respectively. Each of the smart engines 6130 and 6140 may include an LED configured to emit light, a sensor configured to collect information regarding a surrounding environment, a driver configured to drive the LED, and a communication module. The LED included in each of the smart engines 6130 and 6140 may include one of the LEDs 10 and 20 manufactured by the methods of manufacturing the LEDs according to the above-described exemplary embodiments.

The communication module may enable the smart engines 6130 and 6140 to communicate with other peripheral apparatuses according to a communication protocol, such as WiFi, Zigbee®, or LiFi.

In an example, one smart engine 6130 may be connected to another smart engine 6140 to be capable of communicating with the other smart engine 6140. In this case, WiFi extension technology (or WiFi mesh) may be applied to communication between the smart engines 6130 and 6140. At least one smart engine 6130 may be connected by wire or wirelessly to the communication connection device 6100 connected to the communication network 6190. To increase communication efficiency, a plurality of smart engines (e.g., the smart engines 6130 and 6140) may fall into a group and be connected to one communication connection device 6100.

The communication connection device 6100, which is an access point (AP) capable of wired and/or wireless communication, may mediate between the communication network 6190 and other apparatuses. The communication connection device 6100 may be connected to the communication network 6190 by at least one of wired and/or wireless communication methods. For example, the communication connection device 6100 may be mechanically contained in any one of the illumination mechanisms 6120 and 6150.

The communication connection device 6100 may be connected to the mobile device 6200 through a communication protocol, such as WiFi. A user of the mobile device 6200 may receive surrounding environment information, which is collected by the smart engines 6130 and 6140, through the communication connection device 6100 connected to the smart engine 6130 of the illumination mechanism 6120 disposed adjacent thereto. The surrounding environment information may include surrounding traffic information and weather information. The mobile device 6200 may be connected to the communication network 6190 through the communication base station 6180 by using a wireless cellular communication method, such as 3rd generation (3G) or 4th generation (4G).

The server 6160 connected to the communication network 6190 may receive information collected by the smart engines 6130 and 6140 mounted on the illumination mechanisms 6120 and 6150 and monitor operation states of the illumination mechanisms 6120 and 6150. To manage the illumination mechanisms 6120 and 6150 based on monitoring results of the operation states of the illumination mechanisms 6120 and 6150, the server 6160 may be connected to the computer 6170 configured to provide a management system. The computer 6170 may execute software capable of monitoring and managing the operation states of the illumination mechanisms 6120 and 6150 (or operation states of the smart engines 6130 and 6140).

FIG. 33 is a block diagram of an operation of communicating a smart engine of an illumination mechanism including an LED manufactured by a method of manufacturing an LED according to an exemplary embodiment with a mobile device.

Specifically, FIG. 33 is a block diagram of an operation of communicating a smart engine 6130 of an illumination mechanism (refer to 6120 in FIG. 32) with a mobile device 6200 due to visible-light wireless communication. Various communication methods may be applied to transmit information collected by the smart engine 6130 to the mobile device 6200.

Information collected by the smart engine 6130 may be transmitted to the mobile device 6200 via a communication connection device (refer to 6100 in FIG. 32) connected to the smart engine 6130, or the smart engine 6130 and the mobile device 6200 may be connected to one another to be capable of communicating with each other. For example, the smart engine 6130 and the mobile device 5200 may directly communicate with each other by LiFi.

The smart engine 6130 may include a signal processor 6510, a controller 6520, an LED driver 6530, a light source unit 6540, and a sensor 6550. The mobile device 6200 connected to the smart engine 6130 by visible-light wireless communication may include a controller 6410, a light receiving unit 6420, a signal processor 6430, a memory 6440, and an input/output (I/O) unit 6450.

LiFi technology is wireless communication technology that may wirelessly transmit information by using light having a wavelength range, which is visible to the human eyes. The visible-light wireless communication technology may be distinguished from wired optical communication technology and infrared (IR) wireless communication of the related art in that light having a visible wavelength range (e.g., light having a specific visible wavelength range emitted by an LED package according to the present embodiment) is used. Also, the visible-light wireless communication technology may be distinguished from wired optical communication technology of the related art in that a wireless communication environment is used. Also, unlike radio-frequency (RF) wireless communication, the visible-light wireless communication technology may be excellent in user convenience and physical security because frequencies may be freely used without regulation or permission. Furthermore, the visible-light wireless communication technology may be unique because a user may see a communication link with the user's eyes. Further, the visible-light wireless communication technology may be characterized as convergence technology by serving as both a light source and a communication device.

The signal processor 6510 of the smart engine 6130 may process data to be transmitted and received by visible-light wireless communication. In an exemplary embodiment, the signal processor 6510 may convert information collected by the sensor 6550 into data and transmit the data to the controller 6520. The controller 6520 may control operations of the signal processor 6510 and the LED driver 6530. In particular, the controller 6520 may control operations of the LED driver 6530 based on data transmitted by the signal processor 6510. The LED driver 6530 may enable the light source unit 6540 to emit light in response to a control signal transmitted by the controller 6520, and transmit data to the mobile device 6200.

The mobile device 6200 may include the controller 6410, the memory 6440 configured to store data, the I/O unit 6450 including a display, a touch screen, and an audio output unit, and the signal processor 6430 and further include the light receiving unit 6420 configured to recognize visible light including data. The light receiving unit 6420 may sense visible light and convert the visible light into an electric signal. The signal processor 6430 may decode data included in the electric signal converted by the light receiving unit. The controller 6410 may store the data decoded by the signal processor 6430 in the memory 6440 or output the decoded data via the I/O unit 6450 so that a user may recognize the data.

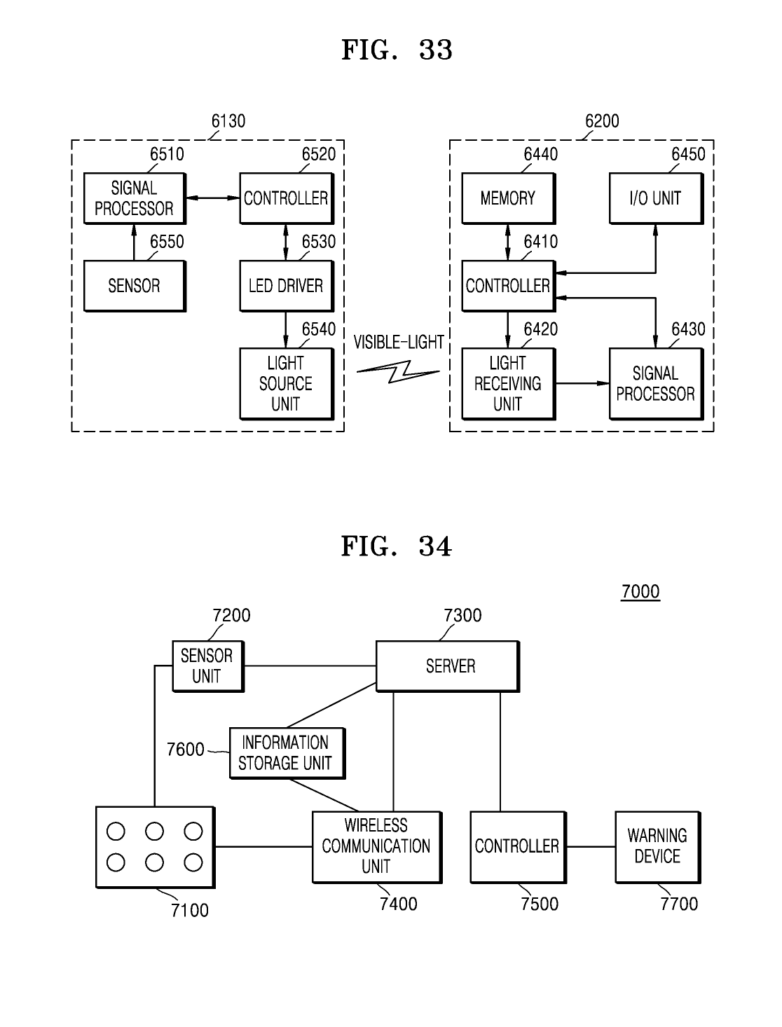

FIG. 34 is a schematic diagram of a smart lighting system. 7000 including an LED manufactured by a method of manufacturing an LED according to an exemplary embodiment.

Specifically, the smart lighting system 7000 may include an illumination unit 7100, a sensor unit 7200, a server 7300, a wireless communication unit 7400, a controller 7500, and an information storage unit 7600. The illumination unit 7100 may include one lighting apparatus or a plurality of lighting apparatuses in a building, and the type of the lighting apparatus is not limited. For example, the illumination unit 7100 may include basic lamps for a living room, a room, a balcony, a kitchen, a bathroom, a staircase, and a front door, and may further include a mood lamp, a stand lamp, or a decorative lamp. The lighting apparatus may include one of the LEDs 10 and 20 manufactured by the methods of manufacturing the LEDs according to the above-described exemplary embodiments.

The sensor unit 7200 may sense illumination states related to the turning on/off of each of the lighting apparatuses and the intensity of a lamp, output sensing signals, and transmit the sensing signals to the server 7300. The sensor unit 7200 may be prepared in a building in which the lighting apparatuses are installed. One sensing unit or a plurality of sensor units 7200 may be located in positions that allow sensing of illumination states of all of the lighting apparatus that are under the control of the smart lighting system 7000. The sensing unit 7200 may be prepared for each lighting apparatus.

Information regarding the illumination states may be transmitted to the server 7300 in real-time or at predetermined intervals, for example, at several minutes or several hours. The server 7300 may be installed inside and/or outside the building. The server 7300 may receive signals from the sensor unit 7200, collect information regarding the illumination states of the turning on/off of the illumination unit 7100 in the building, group the collected information, define illumination patterns based on the grouped information, and provide information regarding the defined illumination patterns to the wireless communication unit 7400. Also, the server 7300 may serve as a medium for transmitting commands received from the wireless communication unit 7400 to the controller 7500.

Specifically, when the sensor unit 7200 senses an illumination state in the building and transmits a sensing signal, the server 7300 may receive the sensing signal, collect information regarding the illumination state, and analyze the information. For example, the server 7300 may classify the collected information into groups according to various periods of time, for example, hour, date, day of the week, weekday/weekend, set specific days, week, or month. Thereafter, the server 7300 may define illumination patterns in average units of days, weeks, weekdays, weekends, and months based on several groups of information and program ‘defined illumination patterns’. The ‘defined illumination patterns’ may be periodically provided to the wireless communication unit 7400 or received from the server 7300 when a user requests information regarding illumination patterns.

Furthermore, in addition to the operation of defining the illumination patterns based on information regarding the illumination states provided by the sensor unit 7200, the server 7300 may provide previously programmed ‘typical illumination patterns’ to the wireless communication unit 7400 based on a typical illumination state sensed in the home. Similar to the ‘defined illumination patterns,’ the ‘typical illumination patterns’ may be periodically provided from the server 7300 or provided at a user's request. FIG. 34 illustrates only one server 7300, but the inventive concept is not limited thereto and at least two servers may be provided. Optionally, the ‘typical illumination pattern’ and/or the ‘defined illumination pattern’ may be stored in the information storage unit 7600. The information storage unit 7600 may be a storage device that may be accessed via a network, which is so-called a cloud.

The wireless communication unit 7400 may select any one of a plurality of illumination patterns provided by the server 7300 and/or the information storage unit 7600 and transmit a command signal for executing or stopping an ‘automatic illumination mode’ to the server 7300. The wireless communication unit 7400 may be one of various portable wireless communication devices (e.g., a smartphone, a tablet PC, a personal digital assistant (PDA), a laptop computer, and a netbook) that may be carried by a user of the smart lighting system 7000.

Specifically, the wireless communication unit 7400 may receive various defined illumination patterns from the server 7300 and/or the information storage unit 7600, select an illumination pattern from the illumination patterns, and transmit a command signal to the server 7300 to execute an ‘automatic illumination mode’ in which the illumination unit 7100 may operate according to the selected illumination pattern. The command signal may be transmitted at a fixed execution time. Alternatively, after the command signal is transmitted without fixing an interruption time, an interruption signal may be transmitted, and the execution of the ‘automatic illumination mode’ may be interrupted.

Furthermore, the wireless communication unit 7400 may further include a function of enabling a user to revise the illumination pattern provided by the server 7300 and/or the information storage unit 7600 or manipulate to input a new illumination pattern. The revised or newly input ‘user setting illumination pattern’ may be transmitted to the wireless communication unit 7400 and automatically transmitted to the server 7300 and/or the information storage unit 7600 or transmitted at a user's request. Also, the wireless communication unit 7400 may receive the ‘defined illumination pattern’ and the ‘typical illumination pattern’ set by the server 7300 from the server 7300 and/or the information storage unit 7600, automatically or by transmitting a provision request signal to the server 7300.

As described above, the wireless communication unit 7400 may transmit and receive required commands or information signals to and from the server 7300 and/or the information storage unit 7600. The server 7300 may serve as a medium among the wireless communication unit 7400, the sensor unit 7200, and the controller 7500 and operate a smart illumination system.

Herein, connection of the wireless communication unit 7400 with the server 7300 may be performed by using, for example, an application, which is an application program of a smartphone. That is, a user may command a server to execute an ‘automatic illumination mode’ via an application downloaded from the smartphone, or provide information regarding a ‘user setting illumination pattern’ on which the user has performed a manipulation or on which the user has made a revision.

A method of providing information regarding the ‘user setting illumination pattern’ may include automatically transmitting the information to the server 7300 and/or the information storage unit 7600 to be stored therein or include performing a manipulation for transmitting the information. The method of providing information may be determined as a basic setting of an application or selected by a user according to options.

The controller 7500 may receive the command signal for executing and stopping the ‘automatic illumination mode’ from the server 7300, control the illumination unit 7100 to execute the command signal, and control one or a plurality of lighting apparatuses. That is, the controller 7500 may control turning on/off and other operations of each lighting apparatus included in the illumination unit 7100 in response to a command of the server 7300.

In addition, the smart illumination system 7000 may further include a warning device 7700 located in a building. When there is an intruder in the building, the warning device 7700 may be configured to warn a user of the intruder.

Specifically, when the user is absent and the ‘automatic illumination mode’ is executed in the building, an intruder may intrude into the building and an abnormal sign deviating from a set illumination pattern may occur. In this case, the sensor unit 7200 may sense the abnormal sign and transmit a warning signal to the server 7300. Also, the server 7300 may inform the wireless communication unit 7400 of the warning signal and simultaneously, transmit a signal to the controller 7500 so that the warning device 7700 may operate in the building.

Furthermore, when the warning signal is transmitted to the server 7300, the server 7300 may further include a system capable of directly informing a security enterprise of an emergency via the wireless communication unit 7400 or a transmission control protocol/Internet protocol (TCP/IP) network.

At least one of the components, elements or units represented by a block as illustrated in the drawings may be embodied as various numbers of hardware, software and/or firmware structures that execute respective functions described above, according to an exemplary embodiment. For example, at least one of these components, elements or units may use a direct circuit structure, such as a memory, processing, logic, a look-up table, etc. that may execute the respective functions through controls of one or more microprocessors or other control apparatuses. Also, at least one of these components, elements or units may be specifically embodied by a module, a program, or a part of code, which contains one or more executable instructions for performing specified logic functions. Also, at least one of these components, elements or units may further include a processor such as a central processing unit (CPU) that performs the respective functions, a microprocessor, or the like. Further, although a bus is not illustrated in some of the block diagrams, communication between the components, elements or units may be performed through the bus. Functional aspects of the above exemplary embodiments may be implemented in algorithms that execute on one or more processors. Furthermore, the components, elements or units represented by a block or processing steps may employ any number of related art techniques for electronics configuration, signal processing and/or control, data processing and the like.

Although a few embodiments have been shown and described, it would be appreciated by those skilled in the art that changes may be made in the exemplary embodiments without departing from the principles and spirit of the disclosure, the scope of which is defined in the claims and their equivalents.

What is claimed is:

1. A method of manufacturing a light emitting diode (LED), the method comprising:
forming a first material layer on a substrate;
forming a second material layer on the first material layer;
forming a photomask pattern on the second material layer;
performing a first etching on the second material layer and a portion of the first material layer by using the photomask pattern as an etch mask;
removing the photomask pattern; and
forming a plurality of isolated structures, by performing a second etching on a remaining portion of the first material layer until a top surface of the substrate is exposed.

2. The method of claim 1, wherein the second material layer has a thickness greater than a thickness of the first material layer.

3. The method of claim 1, wherein the first etching comprises etching the second material layer to form a second material layer pattern having a hemispherical shape or a conic shape.

4. The method of claim 1, wherein the first material layer has a refractive index higher than a refractive index of the substrate, and
the second material layer has a refractive index is lower than the refractive index of the substrate.

5. The method of claim 1, wherein the first material layer comprises a silicon nitride, and the second material layer comprises a silicon oxide.

6. The method of claim 1, wherein the first etching is a dry etching, and the second etching is a wet etching.

7. The method of claim 6, wherein an etchant for the second etching comprises phosphoric acid (H₃PO₄).

8. The method of claim 6, wherein the performing the second etching comprises adjusting an etch selectivity of the first material layer with respect to the second material layer to be at least 5:1.

9. The method of claim 1, wherein the second etching does not substantially etch the substrate.

10. The method of claim 1, further comprising forming a base layer that covers the substrate and the plurality of isolated structures, after the forming of the plurality of isolated structures.

11. A method of manufacturing a light emitting diode (LED), the method comprising:
preparing a substrate having a light transmittance characteristic;
forming a silicon nitride layer on the substrate;
forming a silicon oxide layer on the silicon nitride layer;
forming a photomask pattern on the silicon oxide layer;
dry etching the silicon oxide layer and a portion of the silicon nitride layer by using the photomask pattern as an etch mask;
removing the photomask pattern;
forming a plurality of isolated structures by wet etching a remaining portion of the silicon nitride layer until a top surface of the substrate is exposed;
forming a base layer that covers the substrate and the plurality of isolated structures; and
forming an emission structure on the base layer.

12. The method of claim 11, wherein the substrate comprises a sapphire substrate.

13. The method of claim 11, wherein the emission structure comprises a first-conductivity-type semiconductor layer, an active layer, and a second-conductivity-type semiconductor layer.

14. The method of claim 11, wherein the wet etching does not substantially etch the substrate.

15. The method of claim 11, wherein an etchant for the wet etching comprises a phosphoric acid (H₃PO₄), and a process temperature of the etchant ranges from about 180° C. to about 200° C.

16. The method of claim 11, wherein the plurality of isolated structures respectively have a hemispherical shape or a conic shape.

17. A method of manufacturing a light emitting diode (LED), the method comprising:
forming a plurality of patterns on a substrate, upper portions of the plurality of patterns comprising a first material and lower portions of the plurality of patterns comprising a second material, the second material having a refractive index that is different from a refractive index of the first material; and
forming an emission structure above the plurality of patterns, the emission structure comprising a first-conductivity-type semiconductor layer, an active layer, and a second-conductivity-type semiconductor layer.

18. The method of claim 17, further comprising forming a base layer positioned between the substrate and the emission structure, wherein the base layer covers the plurality of patterns.

19. The method of claim 17, wherein the forming the plurality of patterns comprises performing dry etching to form the upper portions and parts of the lower portions of the plurality of patterns, and performing wet etching to form remaining parts of the lower portions of the plurality of patterns.

20. The method of claim 17, wherein the first material comprises a silicon nitride, and the second material comprises a silicon oxide.
